(19) United States
(12) Patent Application Publication
(10) Pub. No.: US 2005/0156208 A1
(43) Pub. Date: Jul. 21, 2005

(54) Device having multiple silicide types and a method for its fabrication

(75) Inventors: Chun-Chieh Lin, Hsinchu (TW); Wen-Chin Lee, Hsin-Chu (TW); Yee-Chia Yeo, Singapore (SG); Chenming Hu, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/955,349

(22) Filed: Sep. 30, 2004

Related U.S. Application Data
(60) Provisional application No. 60/507,328, filed on Sep. 30, 2003.

(51) Int. Cl. H01L 29/76; H01L 21/336

(52) U.S. Cl. 257/288; 438/197

(57) ABSTRACT

Provided are a semiconductor device and a method for its fabrication. In one example, the semiconductor device includes an active region formed on a substrate using a first silicide type and another active region formed on the substrate using another silicide type. The two silicide types differ and at least one of the two silicides is an alloy silicide. An etch stop layer may overlay at least one of the silicide regions.

### CROSS REFERENCE

This application claims priority from U.S. Provisional Patent Application Ser. No. 60/507,328, filed on Sep. 30, 2003, and is related to U.S. patent application Ser. No. 10/831,021, filed on Apr. 23, 2004, which claims priority from U.S. Provisional Patent Application Ser. No. 60/498,759, filed on Aug. 29, 2003.

### BACKGROUND

The present disclosure relates generally to the field of semiconductor integrated circuits, more particularly, to a device having multiple silicide types and a method of fabricating such device.

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing have been needed.

In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling-down also produces a relatively high power dissipation value, which may be addressed by using low power dissipation devices such as complementary metal-oxide-semiconductor (CMOS) devices.

A CMOS may comprise two different transistors, such as a negative channel MOS (NMOS) and a positive channel MOS (PMOS). As is known, only one of the two transistors is driven at any one time in a CMOS inverter except during a transient switching period. This may lead to a high impedance path between a power line (Vdd) and a ground line (Vss), regardless of the state of the inverter. In other words, there may be almost no current between the power line and ground line except for leaking current. Therefore, a CMOS may implement logic gates which consume only standby power.

In metal-oxide-semiconductor field effect transistor (MOSFET) technologies, a salicide (self-aligned silicide) structure may be implemented. Such a salicide structure may comprise a metal silicide formed atop polysilicon lines, where the polysilicon lines form gates and silicon regions that make up sources and drains for a MOSFET. Metal silicide may be used to provide an interface between metal lines and substrate contact regions, such as a polysilicon gate, a silicon source, and a silicon drain. Placing metal silicide on the source and drain regions may reduce the sheet resistance of the path between the metal contact and the underlying structure. However, although the same silicide is generally used on multiple transistor types, the sheet resistance of different transistors (e.g., NMOS and PMOS) may vary depending on the type of metal or silicide used.

Accordingly, what is needed is a method for fabricating an IC device using multiple types of silicide. It is also desired to provide such a device having such multiple types of silicide, where each type may be adjusted during fabrication. Furthermore, it is desired to minimize silicide loss during contact etching following the fabrication of silicide portions of the device.

### BRIEF DESCRIPTION OF THE DRAWINGS

FIG. 1 is a schematic diagram of exemplary structure illustrating a particular implementation of the present disclosure.

FIG. 2a is a flow chart illustrating a first exemplary method for fabricating the structure of FIG. 1.

FIGS. 2b-2h are cross-sectional views of the structure of FIG. 1 during fabrication using the method of FIG. 2a.

FIG. 3a is a flow chart illustrating a second exemplary method for fabricating the structure of FIG. 1.

FIGS. 3b-3h are cross-sectional views of the structure of FIG. 1 during fabrication using the method of FIG. 3a.

FIG. 4a is a flow chart illustrating a third exemplary method for fabricating the structure of FIG. 1.

FIGS. 4b-4l are cross-sectional views of the structure of FIG. 1 during fabrication using the method of FIG. 4a.

FIG. 5a is a flow chart illustrating a fourth exemplary method for fabricating the structure of FIG. 1.

FIGS. 5b-5i are cross-sectional views of the structure of FIG. 1 during fabrication using the method of FIG. 5a.

FIG. 6a is a flow chart illustrating a fifth exemplary method for fabricating the structure of FIG. 1.

FIGS. 6b-6i are cross-sectional views of the structure of FIG. 1 during fabrication using the method of FIG. 6a.

FIG. 7a is a flow chart illustrating a sixth exemplary method for fabricating the structure of FIG. 1.

FIGS. 7b-7e are cross-sectional views of the structure of FIG. 1 during fabrication using the method of FIG. 7a.

FIG. 8a is a flow chart illustrating a seventh exemplary method for fabricating the structure of FIG. 1.

FIGS. 8b-8k are cross-sectional views of the structure of FIG. 1 during fabrication using the method of FIG. 8a.

### DETAILED DESCRIPTION

The present disclosure relates generally to the field of semiconductor integrated circuits, more particularly, to a device having multiple silicide types and a method of fabricating such device.

It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Generally, both NMOS and PMOS devices are fabricated using the same metal or alloy silicide. Since the silicon source and drain in an NMOS device has a different doping than the silicon source and drain in a PMOS device, the work function of the differently doped drains and sources will be different. Accordingly, it is typically difficult to choose a silicide material that has a work function capable of reducing both NMOS and PMOS source/drain contact sheet resistance.

A device having a complementary silicide structure is disclosed in U.S. Provisional Patent Application Ser. No. 60/498,759, filed on Aug. 29, 2003. The disclosed complementary silicide structure provides complementary silicides for different devices, such as a NMOS and a PMOS. This complementary silicide structure enables the fine-tuning of silicide materials to achieve a desired work function, which aids in reducing contact and series resistance in polysilicon gate and source/drain regions. However, silicide loss during later contact etching may present additional issues. For example, in deep submicron technologies, such as 0.1 μm generations and beyond, the silicide thickness is often less than 350 Å and is generally somewhat sensitive to thickness fluctuations and loss. In addition, it may be difficult to detect and control the endpoint of contact etching for a multiple silicide structure, which may result in additional silicide loss if the contact etching is not stopped at the appropriate time. This silicide loss during contact etching may increase contact resistance, degrade the short channel effect, and increase junction leakage. As will be described in the following disclosure in greater detail, a contact etch stop layer may be used to minimize such silicide loss during contact etching.

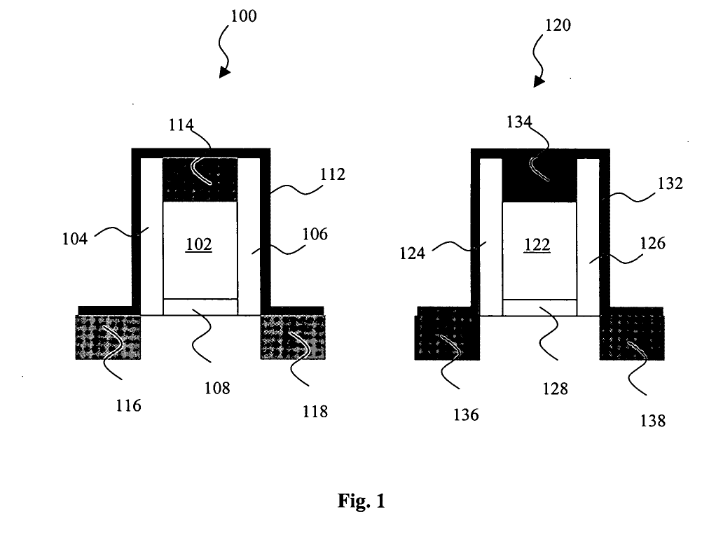

Referring to FIG. 1, in one embodiment, a complementary silicide is provided in a single structure that compromises both an NMOS 100 and a PMOS 120. Both the NMOS 100 and the PMOS 120 may be fabricated on a semiconductor substrate (not shown). The NMOS 100 includes a gate poly-silicon region 102, spacers 104 and 106, gate dielectric 108, gate silicide region 114, a source (not shown) and source silicide region 116, a drain (not shown) and drain silicide region 118, and a contact etch stop layer (CESL or ESL) 112, such as a film. The PMOS 120 includes gate poly-silicon region 122, spacers 124 and 126, gate dielectric 128, gate silicide region 134, a source (not shown) and source silicide region 136, a drain (not shown) and drain silicide region 138, and a contact etch stop layer 132, such as a film. It is understood that other components and/or layers may be present, but are not shown for purposes of clarity.

The semiconductor substrate on which the NMOS 100 and PMOS 120 are fabricated may use an elementary semiconductor such as crystal silicon, polycrystalline silicon, amorphous silicon, germanium, and diamond, a compound semiconductor such as silicon carbide and gallium arsenic, or an alloy semiconductor such as SiGe, GaAsP, AlInAs, AlGaAs, and GaInP or any combination thereof. Furthermore, the semiconductor substrate may be a semiconductor on insulator such as silicon on insulator (SOI). For example, the semiconductor substrate may include a doped epi layer, a gradient semiconductor layer, and/or may further comprise a semiconductor layer overlying a semiconductor layer of a different type such as a silicon layer formed on a silicon germanium layer. In other examples, the compound semiconductor substrate may include a multiple silicon structure or the silicon substrate may include a multilayer compound semiconductor structure.

The NMOS 100 and PMOS 120 may be fabricated using a P-well and N-well structure, and may be fabricated directly onto or within the semiconductor substrate. In the present example, there is an isolation region (not shown) between the NMOS 100 and PMOS 120. The isolation region may utilize isolation technology, such as local oxidation of silicon (LOCOS) and shallow trench isolation (STI). Furthermore, the NMOS and PMOS may have a raised source and drain structure, a FinFET structure, or a double gate structure. In addition, the NMOS and PMOS may include a high-stress film.

The gate dielectric 102 in the NMOS 100 and the gate dielectric 122 in the PMOS 120 may be any suitable dielectric material. Preferably, such material will have relatively high integrity and low current leakage. Examples of such dielectric materials may include silicon oxide, silicon oxynitride, or a high k dielectric, such as hafnium oxide, zirconium oxide, aluminum oxide, a hafnium dioxide-alumina (HfO₂—Al₂O₃) alloy, or combinations thereof. The NMOS gate dielectric 102 and the PMOS gate dielectric 122 may be doped polycrystalline silicon with the same or different doping. Spacers 104 and 106, which are positioned on both sides of the NMOS gate 102, and spacers 124 and 126, which are positioned on the both sides of the PMOS gate 122, may comprise a dielectric material such as silicon nitride, silicon oxide, silicon carbide, silicon oxynitride, or combinations thereof.

The NMOS 100 may include a source and a drain (not shown), which may be formed directly on the semiconductor substrate, in a P-well structure, or using a raised structure. Silicide may be formed on top of the source and drain to form source silicide region 116 and drain silicide region 118, respectively. The silicide may also be formed on top of the polycrystalline silicon gate 102 to form gate silicide region 114. The silicide regions 114, 116, and 118 in the NMOS 100 may comprise such materials as nickel silicide, cobalt silicide, tungsten silicide, tantalum silicide, titanium silicide, platinum silicide, erbium silicide, palladium silicide, or combinations thereof.

The PMOS 120 may include a source and drain (not shown), which may be formed directly on the semiconductor substrate, in a N-well structure, or using a raised structure. Silicide may be formed on top of the source and drain to form source silicide region 136 and drain silicide region 138, respectively. The silicide may also be formed on top of the polycrystalline silicon gate 122 to form gate silicide region 134. The silicide regions 134, 136, and 138 in the PMOS 120 may comprise such materials as nickel silicide, cobalt silicide, tungsten silicide, tantalum silicide, titanium silicide, platinum silicide, erbium silicide, palladium silicide, or combinations thereof.

The contact etch stop layers 112 and 132 may comprise a type of material having a high resistance to contact etch processing, and so may protect the underlying silicide during such contact etch processing. The material of the contact etch stop layers 112, 132 may be selected based on an insulator material that is to be etched during the contact etch processing and an etchant that is to be used. For example, the contact etch stop layers 112, 132 may comprise silicon nitride, silicon oxynitride, silicon carbide, silicon oxide, and combinations thereof. It is understood that, while the contact etch stop layers 112, 132 are denoted by separate reference numbers, they may comprise a single contact etch stop layer.

The contact etch stop layers 112, 132 may be deposited using various methods. For example, the contact etch stop layers 112, 132 may be blanket deposited over a relatively large area that includes the NMOS 100 and the PMOS 120. In some embodiments, the contact etch stop layers 112, 132 may be patterned to cover selected areas, such as only the NMOS 100 or the PMOS 120, or only contact areas such as sources, drains, and gates. If desired, the contact etch stop layers 112, 132 may be removed from the covered areas after the insulator material is removed by contact etching.

In some embodiments, the contact etch stop layers 112 and 132 may be selected and processed to meet predetermined stress criteria. For example, a contact etch stop layer having a tensile stress greater than 1.0 giga pascal may be formed over the NMOS 100. Similarly, a contact etch stop layer having a compressive stress greater than 1.0 giga pascal may be formed over the PMOS 120. The contact etch stop layers 112 and 132, each having a tuned stress, may enhance performance, such as carrier mobility, of the NMOS 100 and PMOS 120.

In the structure of FIG. 1, the silicide formed in silicide regions 114, 116, and 118 of the NMOS 100 (collectively referred to as “the NMOS silicide regions”) is different from the silicide formed in silicide regions 134, 136, and 138 of the PMOS 120 (“the PMOS silicide regions”). For example, the NMOS silicide regions and PMOS silicide regions may both be metal silicides, but of different types, or they may be alloy silicides of different composition, or alloy silicides of the same composition but with different material ratios. Similarly, the NMOS silicide regions may be a metal silicide, while the PMOS silicide regions may be an alloy silicide, or vice versa. Such silicide structures are sometimes referred to as complementary silicide. Complementary silicide may provide flexible fine-tuning of the NMOS silicide and PMOS silicide regions to improve contact resistance, adhesion, and compatibility.

In one example of a complementary silicide structure, different combinations of nickel and cobalt may be used in its implementation. This enables the composition for both the NMOS silicide and the PMOS silicide to be fine tuned for desired work functions and sheet resistances. For example, the NMOS silicide' work function may be tuned below 4.4 eV, while the PMOS silicide' work function may be tuned above 4.6 eV.

It is understood that the complementary silicide structure is not limited to NMOS and PMOS structures, but may be used to form any two silicide regions associated with a semiconductor substrate where the first region has a first type of silicide and the second region has a second type of silicide. Each region may include structures such as a doped silicon or doped poly-silicon area, a source, a drain, and a gate. Furthermore, the structures in each region may comprise a device such as a NMOS, a PMOS, a CMOS, a FINFET, a bipolar transistor, a capacitor, a resistor, or combinations thereof.

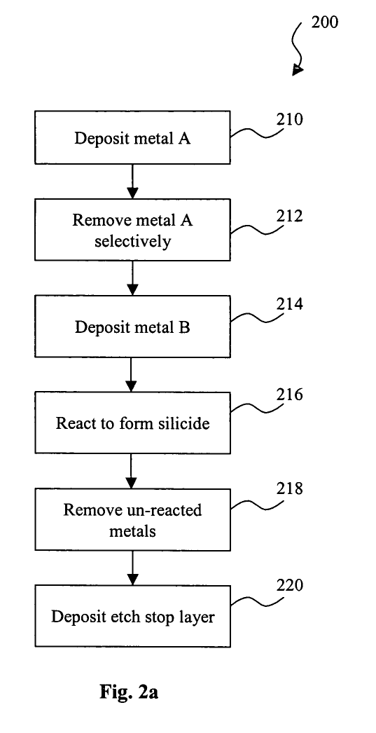

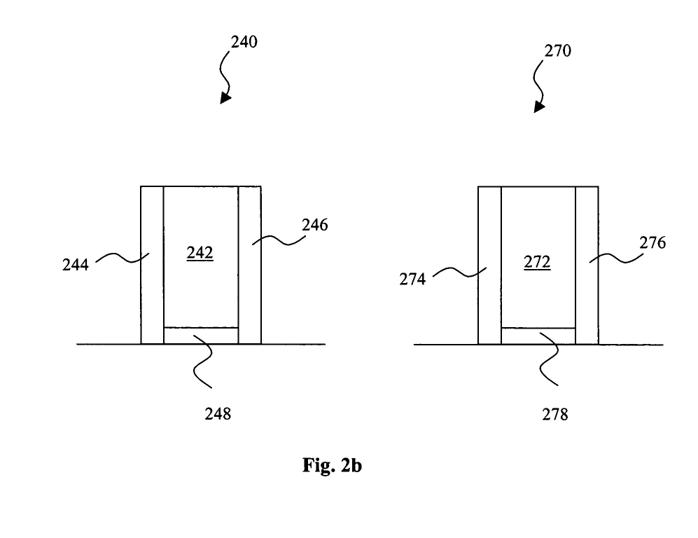

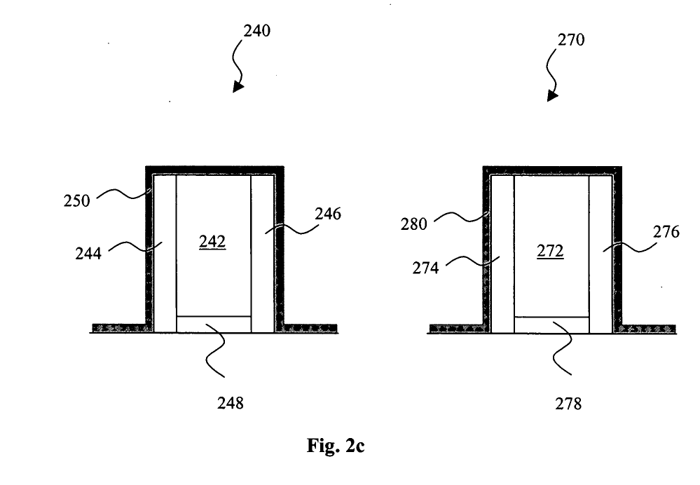

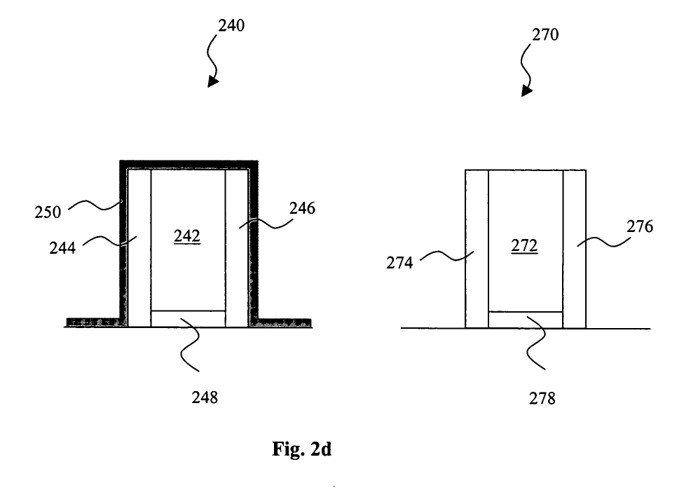

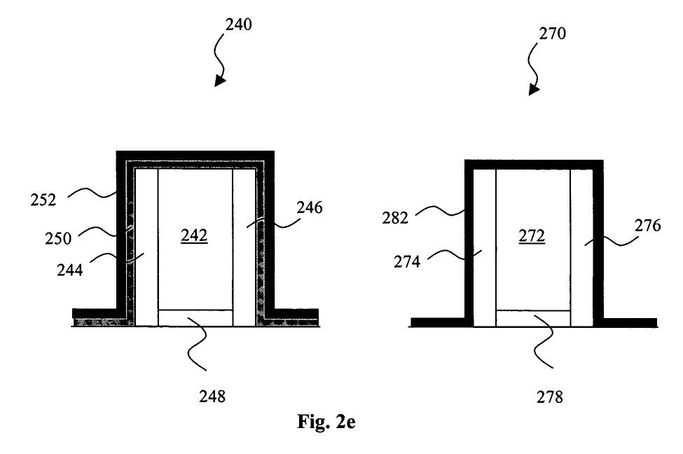

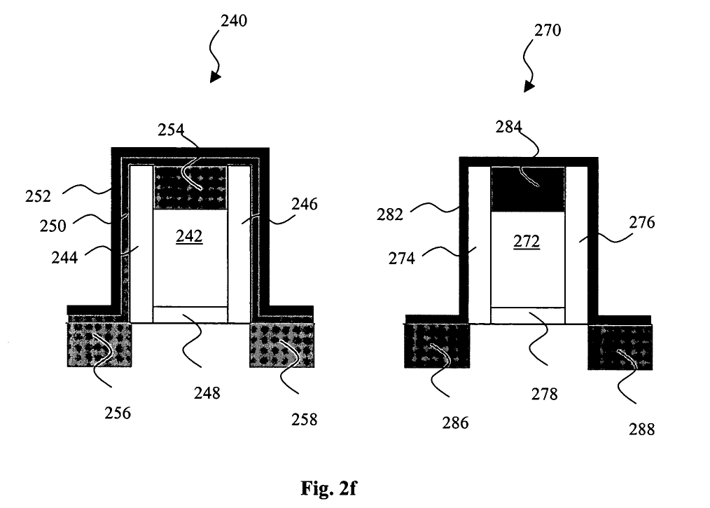

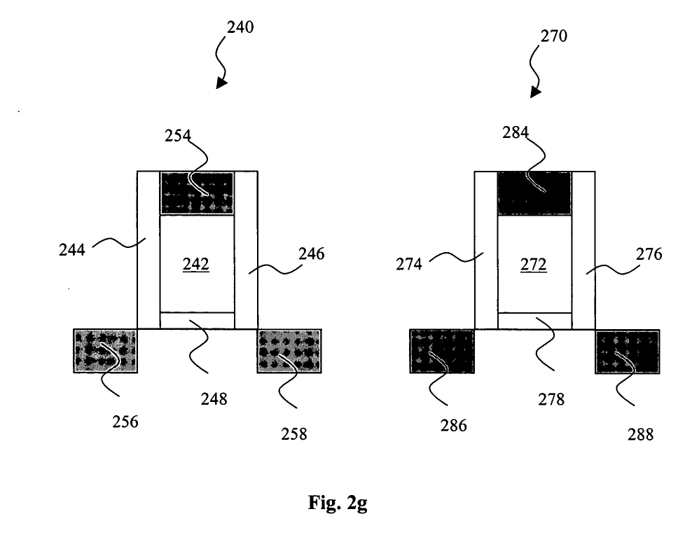

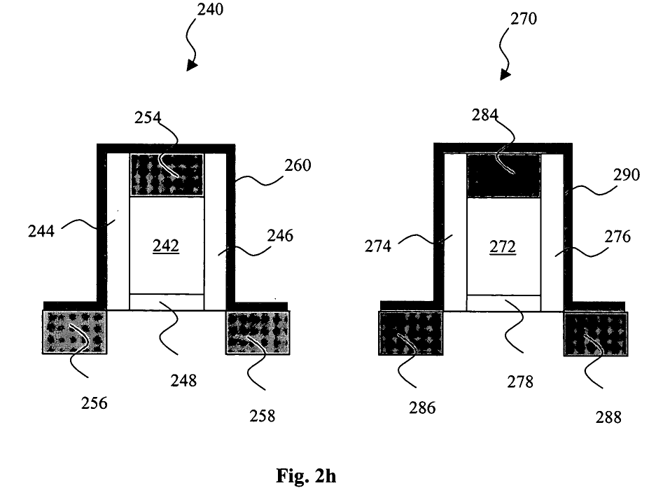

Referring now to FIG. 2a and with additional reference to FIGS. 2b-2h, in one embodiment, a method 200 may be used to form the complementary silicide structure of FIG. 1 with an NMOS and a PMOS. FIGS. 2b-2h illustrate cross-sectional views of an exemplary integrated circuit undergoing fabrication steps that correspond to steps of FIG. 2a. As the method 200 of FIG. 2a is described below in greater detail, the cross-sectional views in FIGS. 2b-2h may also be referred to for purposes of illustration. It is understood that the method 200 is not limited to the formation of a complementary silicide structure for NMOS and PMOS, but may be used to form any two regions during a semiconductor fabrication process where the first region has one composition or material ratio and the second region has a different composition or material ratio.

In the present example, the first region is an NMOS 240 and the second region is a PMOS 270, as illustrated in FIG. 2b. It is understood that portions of the NMOS 240 and PMOS 270 may be fabricated prior to the execution of the method 200. For example, the NMOS 240 includes a polycrystalline silicon gate 242, spacers 244 and 246, and a gate dielectric 248. The PMOS 270 includes a polycrystalline silicon gate 272, spacers 274 and 276, and a gate dielectric 278.

With specific reference now to FIGS. 2a and 2c, the method 200 begins in step 210 with the deposition of first metal portions 250, 280 (which are formed using the same metal ‘A’) over the NMOS 240 and PMOS 270, respectively. The first metal portions 250, 280 may be deposited using physical vapor deposition (PVD) such as sputtering and evaporation, or plating, or chemical vapor deposition (CVD) such as plasma enhanced CVD (PECVD), atmospheric pressure CVD (APCVD), low pressure CVD (LPCVD), high density plasma CVD (HDPCVD) and atomic layer CVD (ALCVD), or other deposition processes. In the present example, a sputtering deposition is used. The first metal portions 250, 280 may be nickel, cobalt, tungsten, tantalum, titanium, platinum, erbium, palladium, or any other metal able to interact with silicon at an elevated temperature to form silicide in a low resistance phase state.

In the present example, the first metal portions 250, 280 comprise nickel, which may offer advantages in silicide technology where the feature size is below 0.13 μm, because nickel generally requires a lower thermal budget than some other suitable metals. This enables nickel silicide to be formed in a single heating step at a relatively low temperature of about 250° C. to about 600° C., with an attendant reduction in silicon consumption in the substrate, thereby enabling the formation of ultra-shallow source/drain junctions. The nickel may be deposited by nickel sputtering, with a suitable process flow including HF dipping, an argon pre-sputter etch to prepare the surface, and then nickel sputtering.

In step 212 and with additional reference to FIG. 2d, the first metal portion 280 may be removed selectively, leaving the first metal portion 250 intact. The first metal portion 280 may be selectively removed using such processes as photolithography and etching that are well know in the art. Such processes may include forming photo-resist on both metal portions 250 and 280, transferring the etching pattern from a mask to the photo-resist, etching, and stripping. Alternatively, the etching may follow the stripping. It is preferable that the etching process be chosen based on the first metal portion 280. For example, if the material is nickel, a wet etching process may be selected using metal etching solution such as sulfuric peroxide mixture (H₂SO₄+H₂O₂+H₂O). If the material is cobalt, a wet etching solution may include a mineral acid (e.g., HCl) and a peroxide solution.

In step 214 and with additional reference to FIG. 2e, second metal portions 252, 282 are deposited over the NMOS 240 and PMOS 270, respectively. The second metal portions 252, 282 are formed using the same metal (metal ‘B’), but it is a different metal or metal composition than that used to form the first metal portions 250, 280. The deposition process may use PVD or CVD. The second metal portions 252, 282 may comprise nickel, cobalt, tungsten, tantalum, titanium, platinum, erbium, palladium, or any other metal able to interact with silicon at an elevated temperature to form silicide in a low resistance phase state. In the present example, the second metal portions 252, 282 are cobalt.

In step 216 and with additional reference to FIG. 2f, a silicide is formed on both the NMOS 240 and the PMOS 270. However, the silicide formed on the NMOS 240 is different than the silicide formed on the PMOS 270. This is because the silicide formed on the NMOS 240 contains both first metal portion 250 (e.g., metal A or nickel) and second metal portion 252 (e.g., metal B or cobalt) (referred to as alloy silicide), while silicide formed on the PMOS 270 contains only second metal portion 282 (cobalt).

As illustrated in FIG. 2f, silicide formed on the gate, source, drain of the NMOS 240 produces gate silicide 254, source silicide 256, and drain silicide 258. Silicide formed on the gate, source, and drain of the PMOS 270 produces gate silicide 284, source silicide 286, and drain silicide 288. The gate silicide 254, source silicide 256, and drain silicide 258 are alloy silicides (nickel and cobalt), while the gate silicide 284, source silicide 286, and drain silicide 288 are cobalt silicide. The A/B metal (e.g., nickel/cobalt) ratio in the alloy silicide may be adjusted to provide a desired work function by optimizing metal deposition processing and silicidation processing. Silicidation processing may be a reaction between the second metal (or first and second metals) and silicon (or poly-silicon) at an elevated temperature that is selected based on the specific metal or metals. Also referred to as annealing, this may use a rapid thermal annealing (RTA) process in a gas atmosphere such as Ar, He, N₂, or other inert gas. Such reacted silicide may be in metastable phase and may need a second annealing step or RTA (e.g., at a higher temperature selected based on a particular metal and intended compound), thereby forming a stable silicide phase with reduced resistance. Such a second annealing step may also be implemented after step 218 (described below) which removes un-reacted metal. It is understood that some silicides, such as nickel silicide, may be formed in a one step RTA at a lower temperature.

In step 218 and with additional reference to FIG. 2g, un-reacted metals may be removed from both the NMOS 240 and the PMOS 270, as well as other areas (not shown), such as an isolation structure. The metal that lies on isolation areas may not have reacted with an oxide or nitride layer, and may need to be selectively removed using a metal etching solution. Such etching may be completed in two steps, wherein each step may use a different etching solution and target for different metals. This will leave intact the silicide on the polysilicon gate and source/drain contact areas. Generally, there is no lithography processing needed to pattern the metal silicide layers for contact because the silicide is aligned to the gate and source/drain areas by the selective reaction and etching (referred to as self-aligned silicide (salicide)).

In step 220 and with additional reference to FIG. 2h, contact etch stop layers 260 and 290 may be formed. As previously described, the contact etch stop layers 260 and 290 may have a relatively high resistance to contact etch processing and may be compatible with silicide (e.g., may adhere relatively well to the silicide, may not react with or defuse into the underlying silicide, etc.). The material of the contact etch stop layers 260, 290 may be selected based on an insulator material (not shown) that is to be etched and an etchant that is to be used. For example, the contact etch stop layers 260, 290 may be formed using silicon nitride, silicon oxynitride, silicon carbide, or silicon oxide (if the insulator material is not silicon oxide).

In the present example, the contact etch stop layers 260, 290 may be blanket deposited over all areas including the NMOS 240 and PMOS 270, although it is understood that a selective deposition process may be used. The selection of a particular deposition method may depend on the material used for the contact etch stop layers 260, 290, and may include PVD, CVD, or a thermal process, and may be completed in multiple steps. For example, a silicon nitride film may be selected for the contact etch stop layers 260, 290. The silicon nitride film may be formed by LPCVD, PECVD, or other known methods. For purposes of illustration, a PECVD process is used, which may provide low temperature processing that is compatible with the underlying structures. For PECVD, the deposition reaction may be silane and ammonia (or nitrogen) in a plasma. SiC may be formed by PECVD of trimethylsilane. The contact etch stop layers 260, 290 may be patterned using photolithography and etching, as is well known in the art.

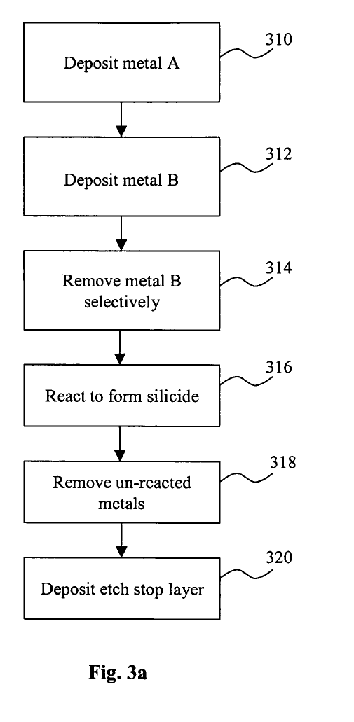

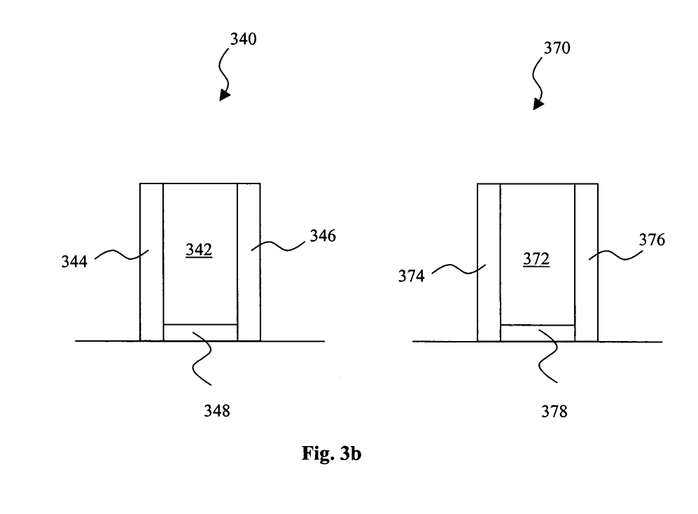

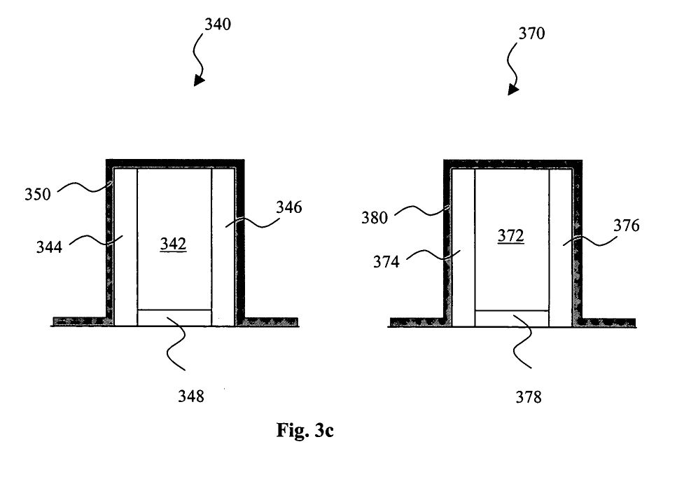

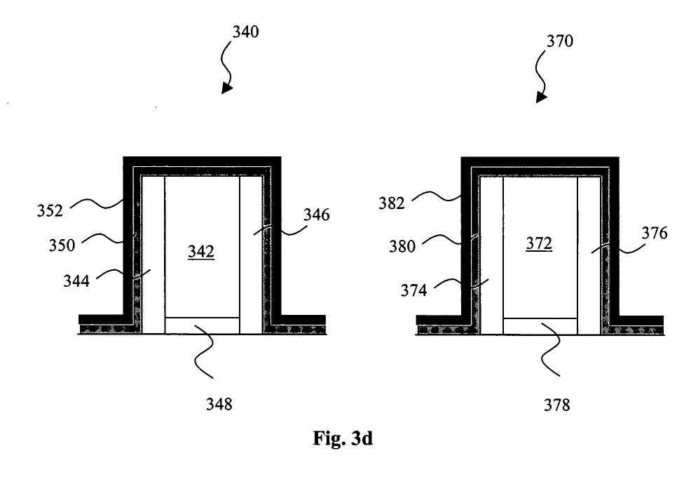

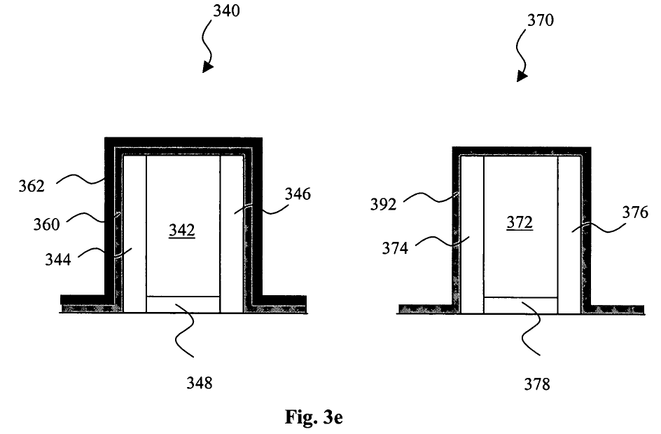

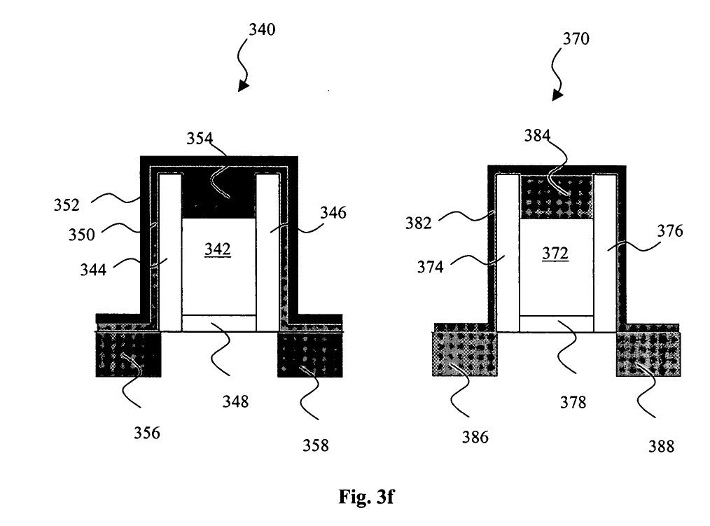

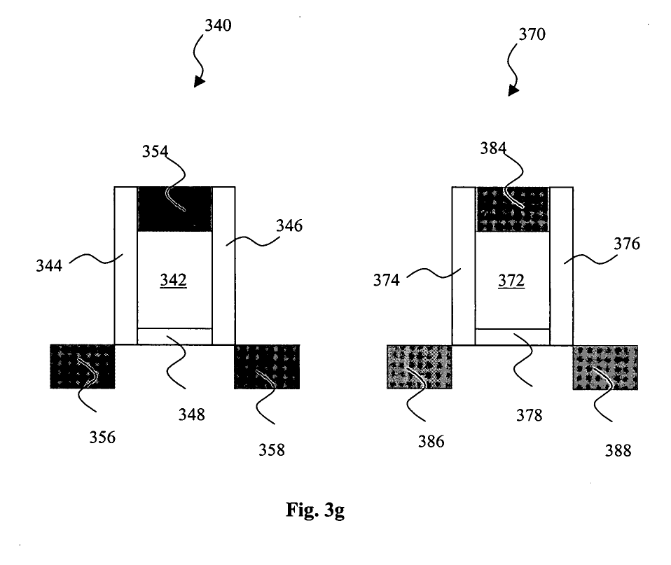

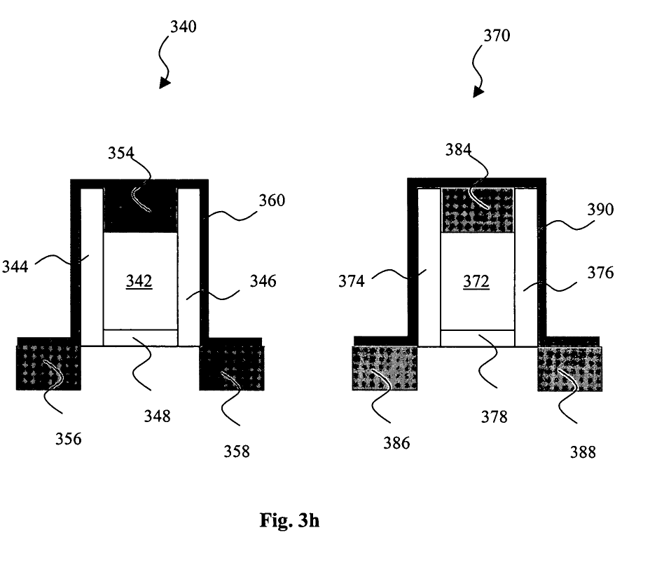

Referring now to FIG. 3a and with additional reference to FIGS. 3b-3h, in another embodiment, a method 300 may be used to form the complementary silicide structure of FIG. 1 with an NMOS and a PMOS. FIGS. 3b-3h illustrate cross-sectional views of an exemplary integrated circuit undergoing fabrication steps that correspond to steps of FIG. 3a. As the method 300 of FIG. 3a is described below in greater detail, the cross-sectional views in FIGS. 3b-3h may also be referred to for purposes of illustration. It is understood that the method 300 is not limited to the formation of a complementary silicide structure, but may be used to form any two regions during a semiconductor fabrication process where the first region has one composition or material ratio and the second region has a different composition or material ratio.

In the present example, the first region is an NMOS 340 and the second region is a PMOS 370, as illustrated in FIG. 3b. It is understood that portions of the NMOS 340 and PMOS 370 may be fabricated prior to the execution of the method 300. For example, the NMOS 340 includes a polycrystalline silicon gate 342, spacers 344 and 346, and a gate dielectric 348. The PMOS 370 includes a polycrystalline silicon gate 372, spacers 374 and 376, and a gate dielectric 378.

With specific reference now to FIGS. 3a and 3c, the method 300 begins in step 310 with the deposition of first metal portions 350, 380 (which are formed using the same metal ‘A’) over the NMOS 340 and PMOS 370, respectively. The first metal portions 350, 380 may be deposited using PVD or CVD processes. The first metal portions 350, 380 may be nickel, cobalt, tungsten, tantalum, titanium, platinum, erbium, palladium, or any other metal able to interact with silicon at an elevated temperature to form silicide in a low resistance phase state. In the present example, the first metal portions 350, 380 comprise nickel. The nickel may be deposited by nickel sputtering, with a suitable process flow including HF dipping, an argon pre-sputter etch to prepare the surface, and then nickel sputtering.

In step 312 and with additional reference to FIG. 3d, second metal portions 352, 382 are deposited over the NMOS 340 and PMOS 370, respectively. The second metal portions 352, 382 are formed using the same metal (metal ‘B’), but it is a different metal or metal composition than that used to form the first metal portions 350, 380. The deposition process may use PVD or CVD. The second metal portions 352, 382 may comprise nickel, cobalt, tungsten, tantalum, titanium, platinum, erbium, palladium, or any other metal able to interact with silicon at an elevated temperature to form silicide in a low resistance phase state. In the present example, the second metal portions 352, 382 are cobalt.

In step 314 and with additional reference to FIG. 3e, the second metal portion 382 may be removed selectively, leaving the second metal portion 352 intact. The second metal portion 382 may be selectively removed using such processes as photolithography and etching. Such processes may include forming photo-resist on both metal portions 352 and 382, transferring the etching pattern from a mask to the photo-resist, etching, and stripping. Alternatively, the etching may follow the stripping. It may be preferable to select the etching process based on the composition of the second metal portion 382.

In step 316 and with additional reference to FIG. 3f, a silicide is formed on both the NMOS 340 and the PMOS 370. However, the silicide formed on the NMOS 340 is different than the silicide formed the PMOS 370. This is because the silicide formed on the NMOS 340 is an alloy silicide that contains both first metal portion 350 (nickel) silicide and second metal portion 352 (cobalt) silicide, while silicide formed on the PMOS 370 contains only second metal portion 382 (cobalt) silicide.

As illustrated in FIG. 3f, silicide formed on the gate, source, drain of the NMOS 340 produces gate silicide 354, source silicide 356, and drain silicide 358. Silicide formed on the gate, source, and drain of the PMOS 370 produces gate silicide 384, source silicide 386, and drain silicide 388. The gate silicide 354, source silicide 356, and drain silicide 358 are alloy silicides (nickel and cobalt), while the gate silicide 384, source silicide 386, and drain silicide 388 are cobalt silicide. The A/B metal (e.g., nickel/cobalt) ratio in the alloy silicide may be adjusted to provide a desired work function by optimizing metal deposition processing and silicidation processing. Silicidation processing may be a reaction between the second metal (or first and second metals) and silicon (or poly-silicon) at an elevated temperature that is selected based on the specific metal or metals. Such reacted silicide may be in metastable phase and may need a second annealing step or RTA, thereby forming a stable silicide phase with reduced resistance. Such a second annealing step may also be implemented after step 318 (described below) which removes un-reacted metal. It is understood that some silicides, such as nickel silicide, may be formed in a one step RTA at a lower temperature.

In step 318 and with additional reference to FIG. 3g, un-reacted metals may be removed from both the NMOS 340 and the PMOS 370, as well as other areas (not shown), such as an isolation structure. The metal that lies on isolation areas may not have reacted with an oxide or nitride layer, and may need to be selectively removed using a metal etching solution. This will leave intact the silicide on the polysilicon gate and source/drain contact areas. Generally, there is no lithography processing needed to pattern the metal silicide layers for contact because the silicide is a self-aligned silicide.

In step 320 and with additional reference to FIG. 3h, contact etch stop layers 360 and 390 may be formed. As previously described, the contact etch stop layers 360 and 390 may have a relatively high resistance to contact etch processing and may be compatible with silicide. The material of the contact etch stop layers 360, 390 may be selected based on an insulator material (not shown) that is to be etched and an etchant that is to be used. For example, the contact etch stop layers 360, 390 may be formed using silicon nitride, silicon oxynitride, silicon carbide, or silicon oxide.

In the present example, the contact etch stop layers 360, 390 may be blanket deposited over all areas including the NMOS 340 and PMOS 370, although it is understood that a selective deposition process may be used. The selection of a particular deposition method may depend on the material used for the contact etch stop layers 360, 390, and may include PVD, CVD, or a thermal process, and may be completed in multiple steps. For example, a silicon nitride film may be selected for the contact etch stop layers 360, 390. The silicon nitride film may be formed by LPCVD, PECVD, or other known methods. For purposes of illustration, a PECVD process is used, which may provide low temperature processing that is compatible with the underlying structures. For PECVD, the deposition reaction may be silane and ammonia (or nitrogen) in a plasma. SiC may be formed by PECVD of trimethylsilane. The contact etch stop layers 360, 390 may be patterned using photolithography and etching, as is well known in the art.

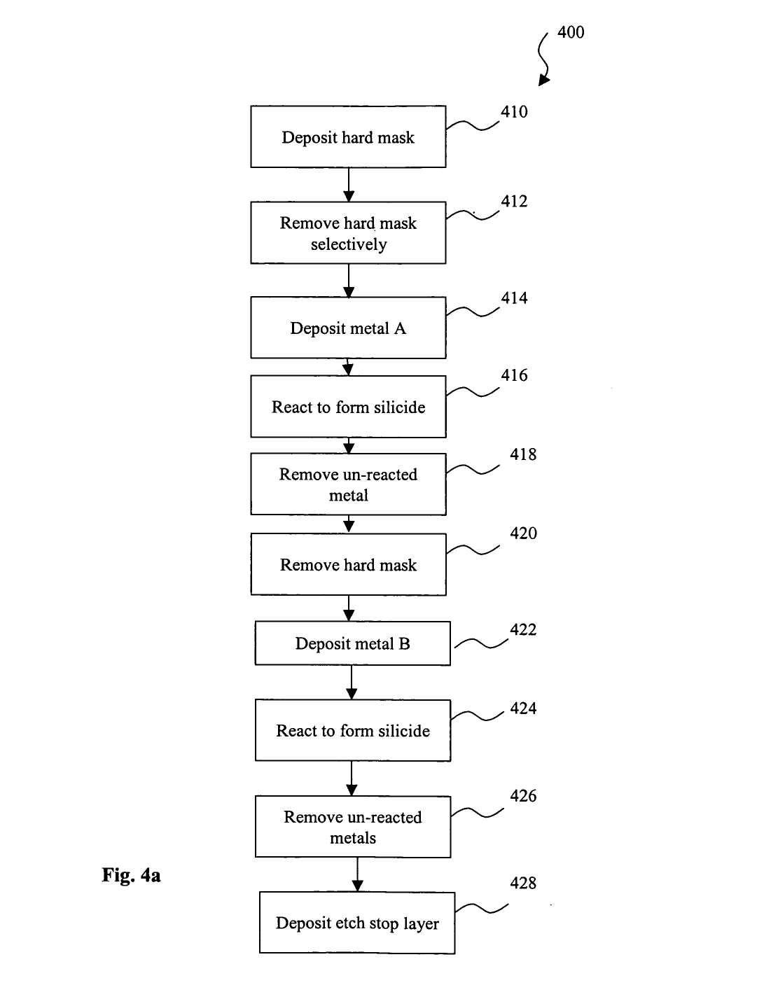

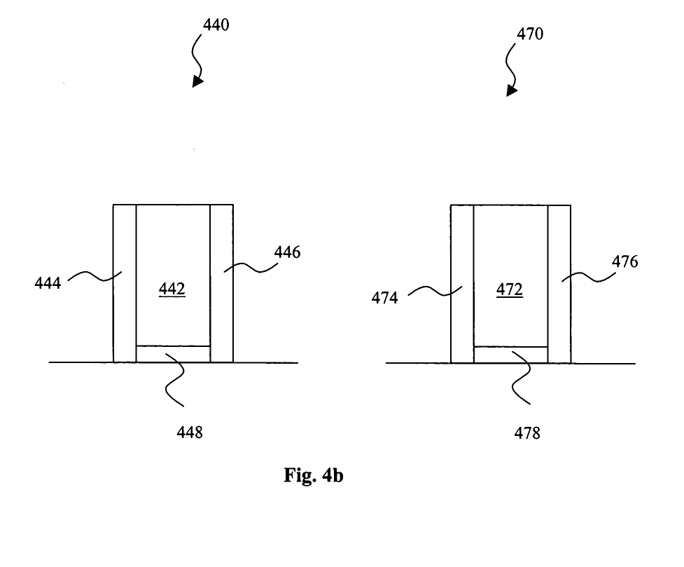

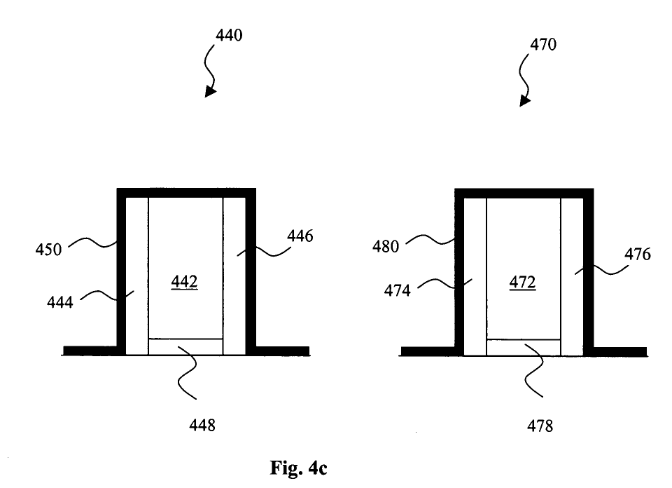

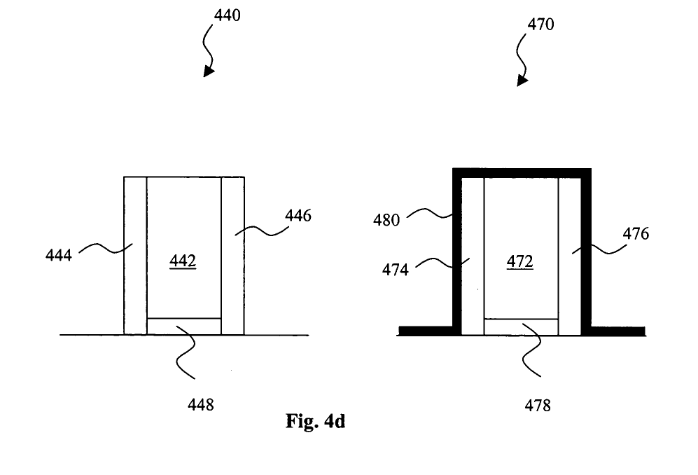

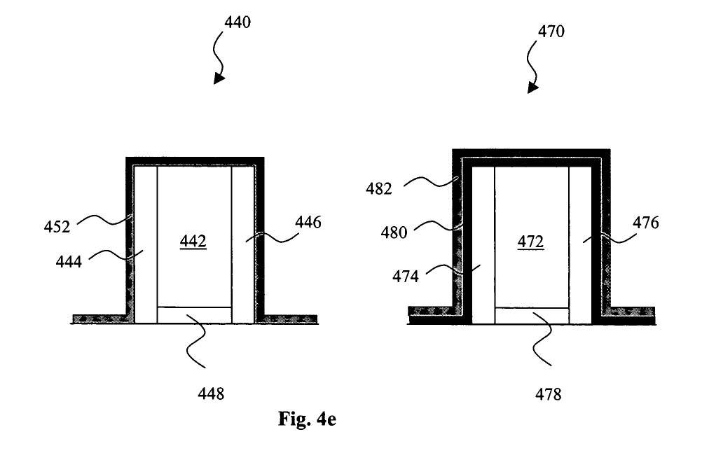

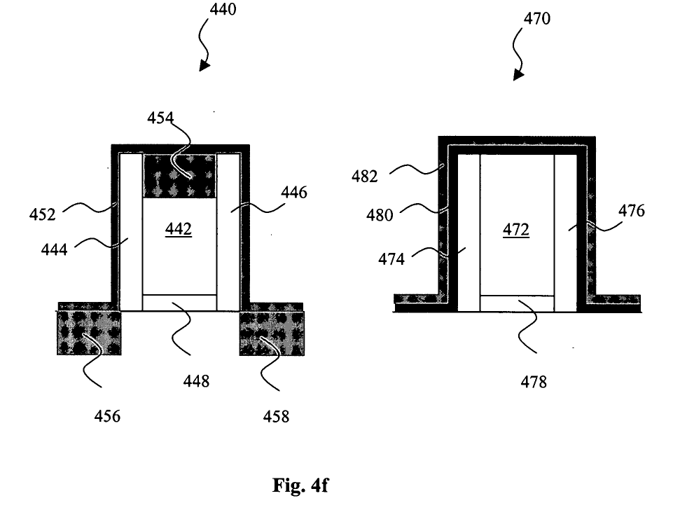

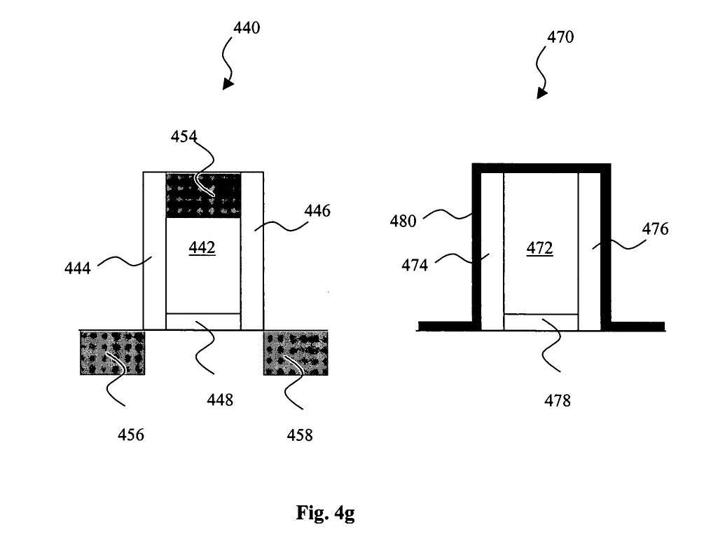

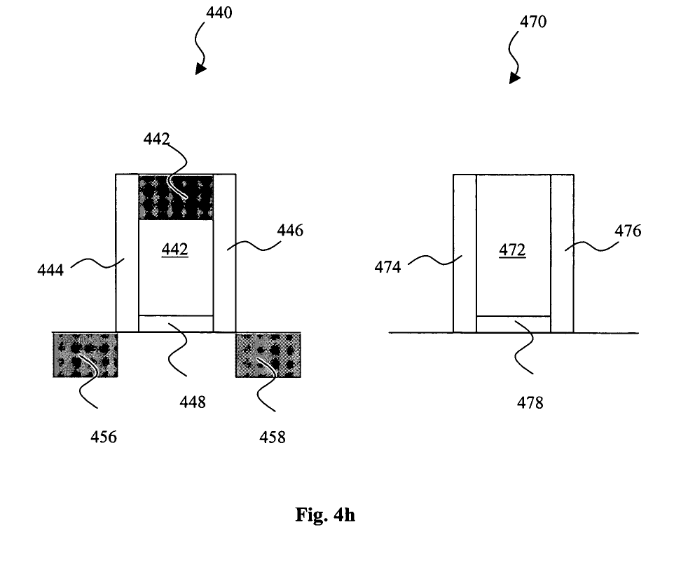

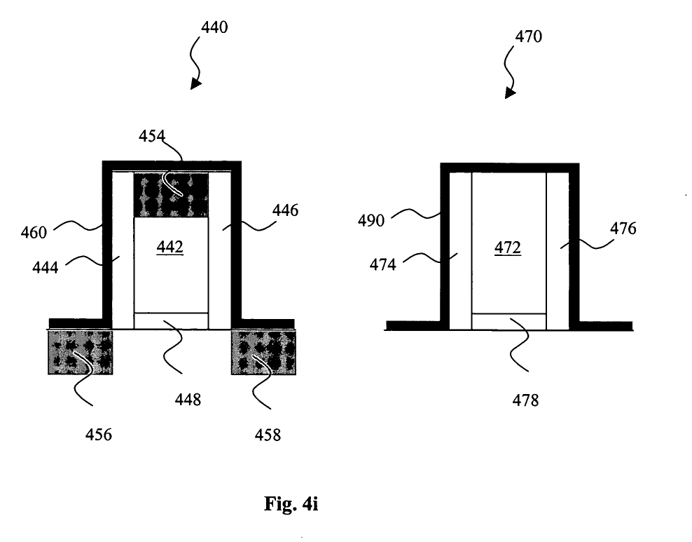

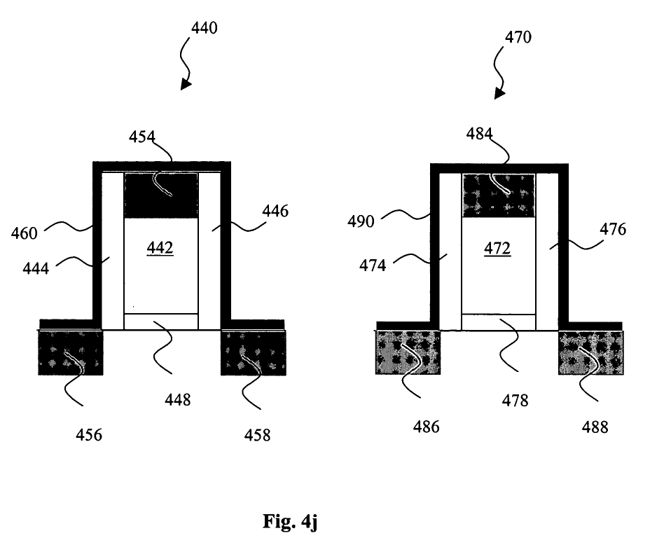

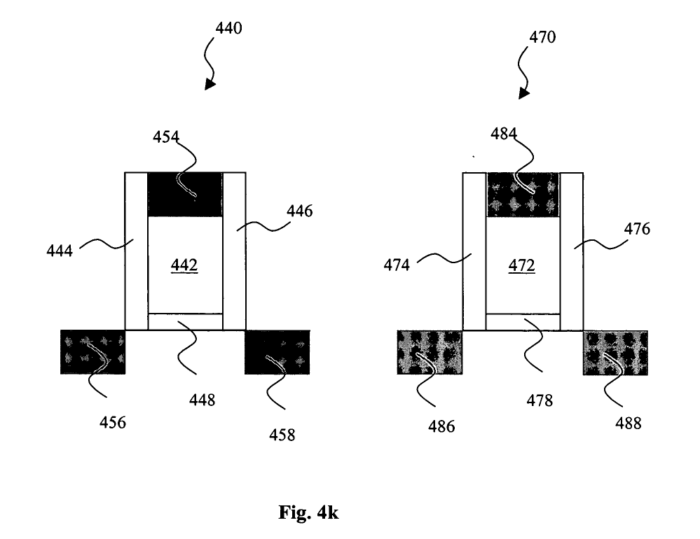

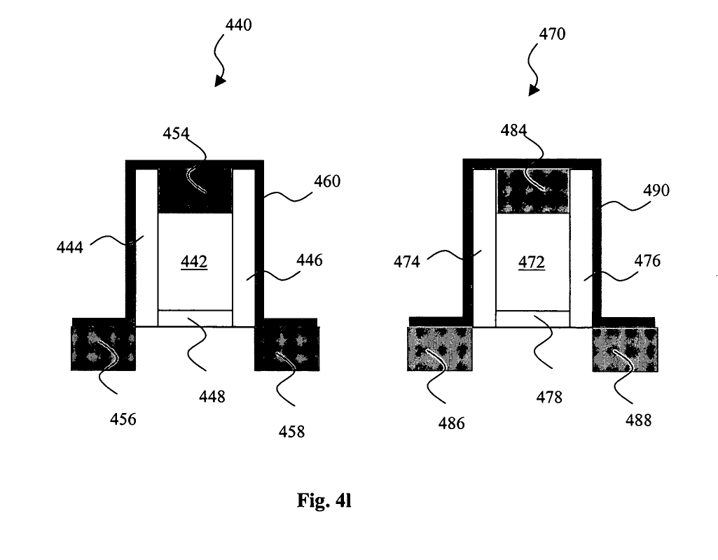

Referring now to FIG. 4a and with additional reference to FIGS. 4b-4l, in yet another embodiment, a method 400 may be used to form the complementary silicide structure of FIG. 1 with an NMOS and a PMOS. FIGS. 4b-4l illustrate cross-sectional views of an exemplary integrated circuit undergoing fabrication steps that correspond to steps of FIG. 4a. As the method 400 of FIG. 4a is described below in greater detail, the cross-sectional views in FIGS. 4b-4l may also be referred to for purposes of illustration. It is understood that the method 400 is not limited to the formation of a complementary silicide structure, but may be used to form any two regions during a semiconductor fabrication process where the first region has one composition or material ratio and the second region has a different composition or material ratio.

In the present example, the first region is an NMOS 440 and the second region is a PMOS 470, as illustrated in FIG. 4b. It is understood that portions of the NMOS 440 and PMOS 470 may be fabricated prior to the execution of the method 400. For example, the NMOS 440 includes a polycrystalline silicon gate 442, spacers 444 and 446, and a gate dielectric 448. The PMOS 470 includes a polycrystalline silicon gate 472, spacers 474 and 476, and a gate dielectric 478.

With specific reference now to FIGS. 4a and 4c, the method 400 begins in step 410 with the deposition of hard mask portions 450, 480 over the NMOS 440 and PMOS 470, respectively. The hard mask portions 450, 480 may be deposited using PVD processes, CVD processes, or a high temperature interaction between nitrogen or oxygen gases. The hard mask portions 450, 480 may include silicon oxide, silicon nitride, silicon carbide, or a combination thereof. For example, silicon nitride may be formed by high temperature CVD, LPCVD, or PECVD. LPCVD silicon nitride may be formed by reacting dichlorosilane (SiCl₂H₂) and ammonia (NH₃). Silicon oxide may be formed by thermal oxidation or CVD processes. Silicon carbide may be formed based on PECVD using trimeththylsilane.

In step 412 and with additional reference to FIG. 4d, the hard mask portion 450 may be removed selectively, leaving the hard mask portion 480 intact. The hard mask portion 450 may be selectively removed using such processes as photolithography and etching that are well know in the art. Such processes may include forming photo-resist on both hard mask portions 450 and 480, transferring the etching pattern from a mask to the photo-resist, etching, and stripping. Alternatively, the etching may follow the stripping. It may be preferable to select the etching process based on the material forming the hard mask. For example, after the photo-resist is applied, exposed, and developed, a silicon nitride hard mask may be dry etched according to a pre-designed pattern transferred from an optical mask to the photo-resist.

In step 414 and with additional reference to FIG. 4e, first metal portions 452, 482 are deposited over the NMOS 440 and PMOS 470, respectively. The first metal portions 452, 482 are formed using the same metal (metal ‘A’). The deposition process may use PVD or CVD. The second metal portions 252, 282 may comprise nickel, cobalt, tungsten, tantalum, titanium, platinum, erbium, palladium, or any other metal able to interact with silicon at an elevated temperature to form silicide in a low resistance phase state. In the present example, the first metal portions 452, 482 are nickel.

In step 416 and with additional reference to FIG. 4f, a silicide is formed on the NMOS 440. The silicide formed on the NMOS 240 contains only first metal portion 452 (e.g., metal A or nickel) silicide. However, because the PMOS 470 is covered by the hard mask portion 480, the metal A (nickel) that comprises the first metal portion 482 is unable to interact with the silicon or poly-silicon of the PMOS 470.

As shown in FIG. 4f, silicide formed on the gate, source, drain of the NMOS 340 produces gate silicide 454, source silicide 456, and drain silicide 458. Silicidation processing may be a reaction between metal A and silicon (or poly-silicon) at an elevated temperature that is selected based on the specific metal or metals. The silicidation process may include a second annealing step that anneals reacted silicide in metastable phase and forms a stable silicide phase with reduced resistance. Such a second annealing step may also be implemented after step 418 (described below), which removes un-reacted metal. It is understood that some silicides, such as nickel silicide, may be formed in a one step RTA at a lower temperature.

In step 418 and with additional reference to FIG. 4g, un-reacted metals may be removed from both the NMOS 440 and the PMOS 470, as well as other areas such as an isolation structure (not shown). The un-reacted metal associated with the NMOS 440 comprises the residuals of metal A after the silicidation of step 416. Metal associated with isolation areas, nitride/oxide spacers, and the PMOS 470 (which is covered by the hard mask) is not reacted with an oxide or nitride layer, and may be removed using a metal etching, leaving intact the silicide on the polysilicon gate and source/drain contact areas on the NMOS 440.

In step 420 and with additional reference to FIG. 4h, the hard mask portion 480 is removed from the PMOS 470. The hard mask portion 480 may be removed by an etching process, such as wet etching or dry etching. For example, in wet etching, an etching solution may be selected that has a high etching selectivity between silicon nitride and other materials, including silicon oxide and metal silicide.

In step 422 and with additional reference to FIG. 4i, second metal portions 460, 490 are deposited over the NMOS 440 and PMOS 470, respectively. The second metal portions 460,490 are formed using the same metal (metal ‘B’), but it is a different metal or metal composition than that used to form the first metal portions 452, 482. The deposition process may use PVD or CVD. The second metal portions 460, 490 may comprise nickel, cobalt, tungsten, tantalum, titanium, platinum, erbium, palladium, or any other metal able to interact with silicon at an elevated temperature to form silicide in a low resistance phase state. In the present example, the second metal portions 460, 490 are cobalt.

In step 424 and with additional reference to FIG. 4j, a silicide is formed on both the NMOS 440 and the PMOS 470. However, the silicide formed on the NMOS 440 is different than the silicide formed the PMOS 470. This is because the silicide formed on the NMOS 440 is an alloy silicide that contains both first metal portion 452 (e.g., metal A or nickel) silicide and second metal portion 460 (e.g., metal B or cobalt) silicide, while silicide formed on the PMOS 470 contains only second metal portion 490 (cobalt) silicide.

As illustrated in FIG. 4j, silicide formed on the gate, source, drain of the NMOS 440 produces gate silicide 454, source silicide 456, and drain silicide 458. Silicide formed on the gate, source, and drain of the PMOS 470 produces gate silicide 384, source silicide 486, and drain silicide 488. The gate silicide 454, source silicide 456, and drain silicide 458 are alloy silicides (nickel and cobalt), while the gate silicide 484, source silicide 486, and drain silicide 488 are cobalt silicides.

As previously described, the metal A silicide on the NMOS 440 was initially formed during step 416. In the current step 424, the metal A silicide on the NMOS 440 interacts with the metal B to form an alloy silicide. The A/B metal (e.g., nickel/cobalt) ratio in the alloy silicide may be adjusted to provide a desired work function by optimizing metal deposition processing and silicidation processing. Silicidation processing may be a reaction between the second metal (or first and second metals) and silicon (or poly-silicon) at an elevated temperature that is selected based on the specific metal or metals. Such reacted silicide may be in metastable phase and may need a second annealing step or RTA, thereby forming a stable silicide phase with reduced resistance. Such a second annealing step may also be implemented after the step 318 (described below) which removes un-reacted metal. It is understood that some silicides, such as nickel silicide, may be formed in a one step RTA at a lower temperature.

In step 426 and with additional reference to FIG. 4k, un-reacted metals may be removed from both the NMOS 440 and the PMOS 470, as well as other areas (not shown), such as an isolation structure. The metal that lies on isolation areas may not have reacted with an oxide or nitride layer, and may need to be selectively removed using a metal etching solution. This will leave intact the silicide on the polysilicon gate and source/drain contact areas.

In step 428 and with additional reference to FIG. 4l, contact etch stop layers 460 and 490 may be formed. As previously described, the contact etch stop layers 460 and 490 may have a relatively high resistance to contact etch processing and may be compatible with silicide. The material of the contact etch stop layers 460, 490 may be selected based on an insulator material (not shown) that is to be etched and an etchant that is to be used. For example, the contact etch stop layers 460, 490 may be formed using silicon nitride, silicon oxynitride, silicon carbide, or silicon oxide.

In the present example, the contact etch stop layers 460, 490 may be blanket deposited over all areas including the NMOS 440 and PMOS 470, although it is understood that a selective deposition process may be used. The selection of a particular deposition method may depend on the material used for the contact etch stop layers 460, 490, and may include PVD, CVD, or a thermal process, and may be completed in multiple steps. For example, a silicon nitride film may be selected for the contact etch stop layers 460, 490. The silicon nitride film may be formed by LPCVD, PECVD, or other known methods. For purposes of illustration, a PECVD process is used, which may provide low temperature processing that is compatible with the underlying structures. For PECVD, the deposition reaction may be silane and ammonia (or nitrogen) in a plasma. SiC may be formed by PECVD of trimethylsilane. The contact etch stop layers 460, 490 may be patterned using photolithography and etching, as is well known in the art.

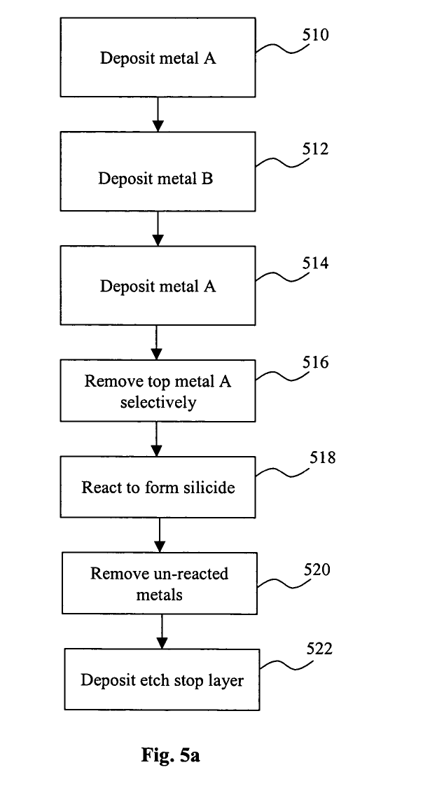

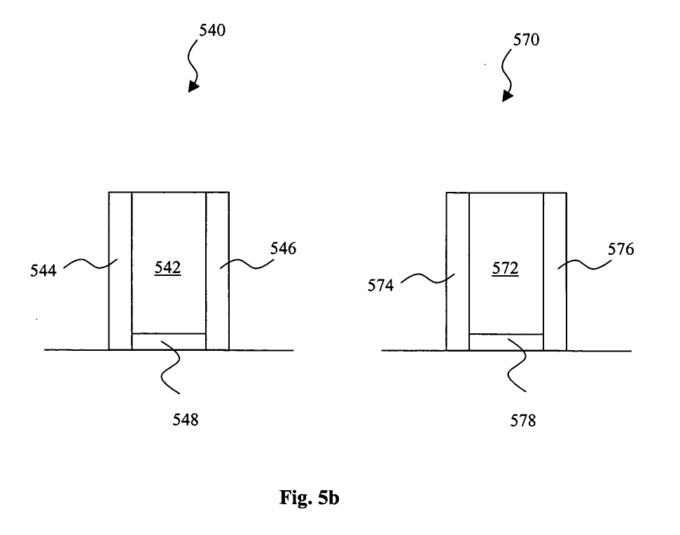

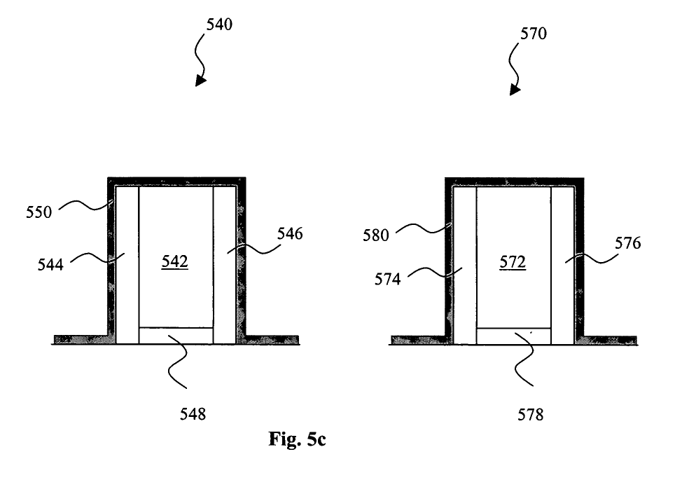

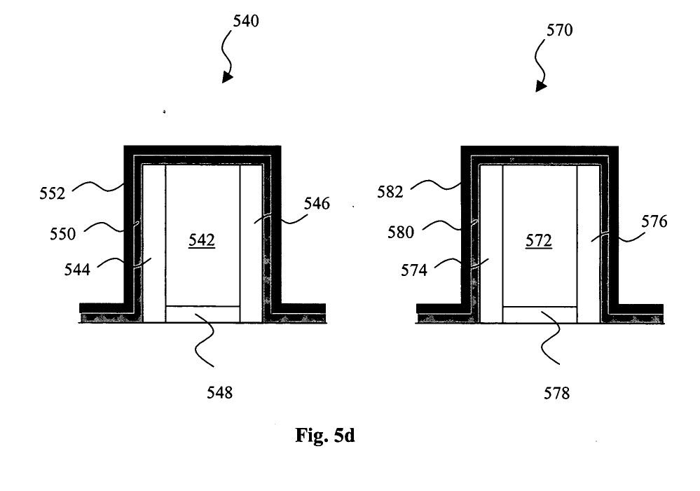

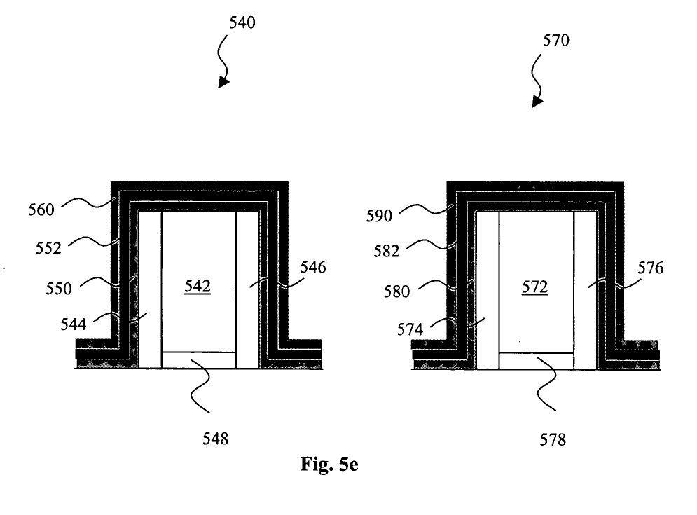

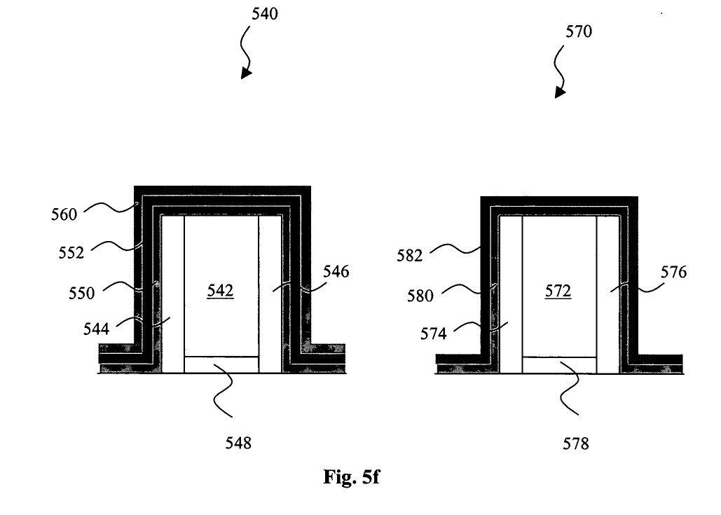

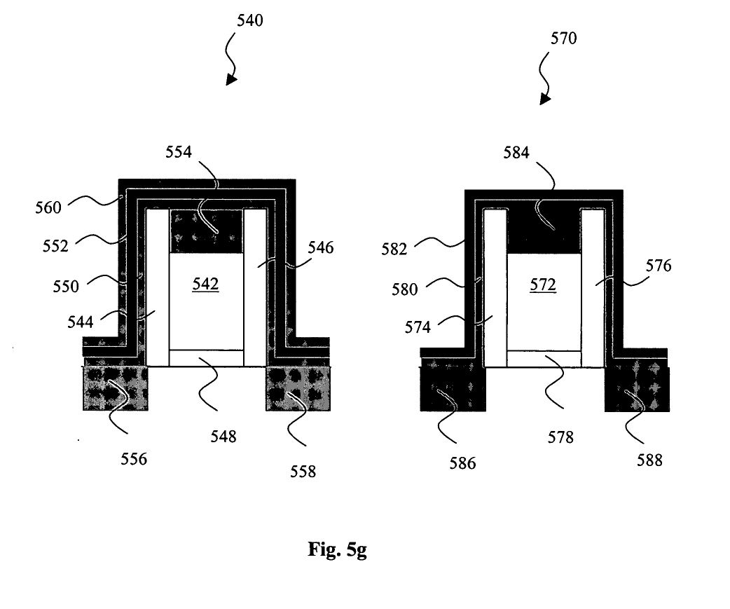

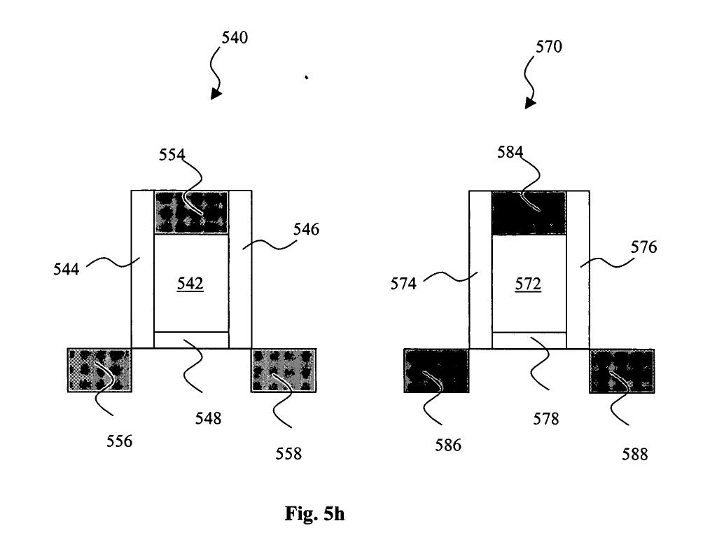

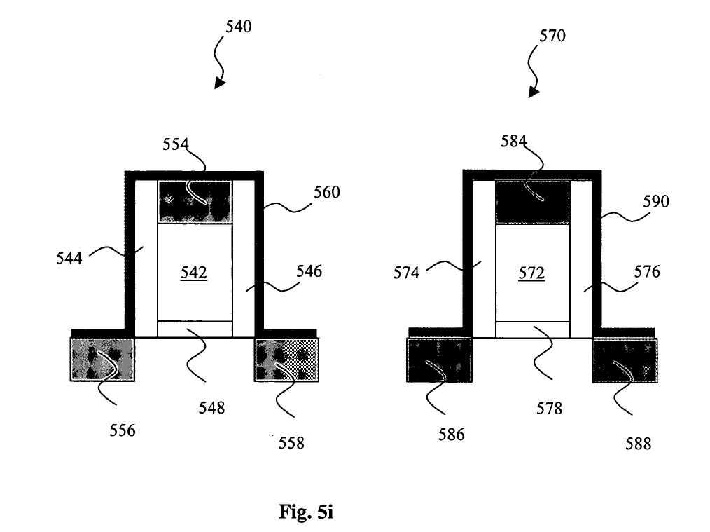

Referring now to FIG. 5a and with additional reference to FIGS. 5b-5i, in still another embodiment, a method 500 may be used to form the complementary silicide structure of FIG. 1 with an NMOS and a PMOS. FIGS. 5b-5i illustrate cross-sectional views of an exemplary integrated circuit undergoing fabrication steps that correspond to steps of FIG. 5a. As the method 500 of FIG. 5a is described below in greater detail, the cross-sectional views in FIGS. 5b-5i may also be referred to for purposes of illustration. It is understood that the method 500 is not limited to the formation of a complementary silicide structure, but may be used to form any two regions during a semiconductor fabrication process where the first region has one composition or material ratio and the second region has a different composition or material ratio.

In the present example, the first region is an NMOS 540 and the second region is a PMOS 570, as illustrated in FIG. 5b. It is understood that portions of the NMOS 540 and PMOS 570 may be fabricated prior to the execution of the method 500. For example, the NMOS 540 includes a polycrystalline silicon gate 542, spacers 544 and 546, and a gate dielectric 548. The PMOS 570 includes a polycrystalline silicon gate 572, spacers 574 and 576, and a gate dielectric 578.

With specific reference now to FIGS. 5a and 5c, the method 500 begins in step 510 with the deposition of first metal portions 550, 580 (which are formed using the same metal ‘A’) over the NMOS 540 and PMOS 570, respectively. The first metal portions 550, 580 may be deposited using PVD or CVD processes. The first metal portions 550, 580 may be nickel, cobalt, tungsten, tantalum, titanium, platinum, erbium, palladium, or any other metal able to interact with silicon at an elevated temperature to form silicide in a low resistance phase state. In the present example, the first metal portions 550, 580 comprise nickel. The nickel may be deposited by nickel sputtering, with a suitable process flow including HF dipping, an argon pre-sputter etch to prepare the surface, and then nickel sputtering.

In step 512 and with additional reference to FIG. 5d, second metal portions 552, 582 are deposited over the NMOS 540 and PMOS 570, respectively. The second metal portions 552, 582 are formed using the same metal (metal ‘B’), but it is a different metal or metal composition than that used to form the first metal portions 550, 580. The deposition process may use PVD or CVD. The second metal portions 552, 582 may comprise nickel, cobalt, tungsten, tantalum, titanium, platinum, erbium, palladium, or any other metal able to interact with silicon at an elevated temperature to form silicide in a low resistance phase state. In the present example, the second metal portions 552, 582 are cobalt.

In step 514 and with additional reference to FIG. 5e, third metal portions 560, 590 are deposited over the NMOS 540 and PMOS 570, respectively. The third metal portions 560, 590 are formed using the same metal (metal ‘A’) as the first metal portions 550, 580. This forms a “sandwich” structure with a layer of metal B formed between two layers of metal A (e.g., nickel/cobalt/nickel). The deposition process may use PVD or CVD. The third metal portions 560, 590 may comprise nickel, cobalt, tungsten, tantalum, titanium, platinum, erbium, palladium, or any other metal able to interact with silicon at an elevated temperature to form silicide in a low resistance phase state. In the present example, the third metal portions 560, 590 are nickel. The nickel may be deposited by a process such as nickel sputtering, with a suitable process flow including HF dipping, an argon pre-sputter etch to prepare the surface, and then nickel sputtering.

In step 516 and with additional reference to FIG. 5f, the third metal portion 590 may be removed selectively, leaving the third metal portion 560 intact. The third metal portion 590 may be selectively removed using such processes as photolithography and etching. Such processes may include forming photo-resist on both metal portions 560 and 590, transferring an etching pattern from a mask to the photo-resist, etching, and stripping. Alternatively, the etching may follow the stripping. It may be preferable to select the etching process based on the third metal portion 590. For example, if the material is nickel, a wet etching process may be selected using a metal etching solution such as a sulfuric peroxide mixture.

In step 518 and with additional reference to FIG. 5g, a silicide is formed on both the NMOS 540 and the PMOS 570. However, the silicide formed on the NMOS 540 is different than the silicide formed the PMOS 570. This is because the silicide formed on the NMOS 540 is an alloy silicide that contains a relatively large amount of metal A (e.g., nickel), while silicide formed on the PMOS 570 contains a lesser amount of metal A. In other words, both are alloy silicides containing metals A and B (e.g., nickel and cobalt), but with different compositions.

As illustrated in FIG. 5g, silicide formed on the gate, source, drain of the NMOS 540 produces gate silicide 554, source silicide 556, and drain silicide 558. Silicide formed on the gate, source, and drain of the PMOS 570 produces gate silicide 584, source silicide 586, and drain silicide 588. The gate silicide 554, source silicide 556, and drain silicide 558 are alloy silicides with a relatively high level of metal A (nickel), while the gate silicide 584, source silicide 586, and drain silicide 588 are alloy silicides with a lower level of metal A. The A/B metal (e.g., nickel/cobalt) ratio in the alloy silicides may be adjusted to provide a desired work function by optimizing metal deposition processing and silicidation processing. Silicidation processing may be a reaction between the second metal (or first and second metals) and silicon (or poly-silicon) at an elevated temperature that is selected based on the specific metal or metals. Such reacted silicide may be in metastable phase and may need a second annealing step or RTA, thereby forming a stable silicide phase with reduced resistance. Such a second annealing step may also be implemented after the step 520 (described below) which removes un-reacted metal. It is understood that some silicides, such as nickel silicide, may be formed in a one step RTA at a lower temperature.

In step 520 and with additional reference to FIG. 5h, un-reacted metals may be removed from both the NMOS 540 and the PMOS 570, as well as other areas (not shown), such as an isolation structure. The metal that lies on isolation areas may not have reacted with an oxide or nitride layer, and may need to be selectively removed using a metal etching solution. This will leave intact the silicide on the polysilicon gate and source/drain contact areas.

In step 552 and with additional reference to FIG. 5i, contact etch stop layers 560 and 590 may be formed. As previously described, the contact etch stop layers 560 and 590 may have a relatively high resistance to contact etch processing and may be compatible with silicide. The material of the contact etch stop layers 560, 590 may be selected based on an insulator material (not shown) that is to be etched and an etchant that is to be used. For example, the contact etch stop layers 560, 590 may be formed using silicon nitride, silicon oxynitride, silicon carbide, or silicon oxide.

In the present example, the contact etch stop layers 560, 590 may be blanket deposited over all areas including the NMOS 540 and PMOS 570, although it is understood that a selective deposition process may be used. The selection of a particular deposition method may depend on the material used for the contact etch stop layers 560, 590, and may include PVD, CVD, or a thermal process, and may be completed in multiple steps. For example, a silicon nitride film may be selected for the contact etch stop layers 560, 590. The silicon nitride film may be formed by LPCVD, PECVD, or other known methods. For purposes of illustration, a PECVD process is used, which may provide low temperature processing that is compatible with the underlying structures. For PECVD, the deposition reaction may be silane and ammonia (or nitrogen) in a plasma. SiC may be formed by PECVD of trimethylsilane. The contact etch stop layers 560, 590 may be patterned using photolithography and etching, as is well known in the art.

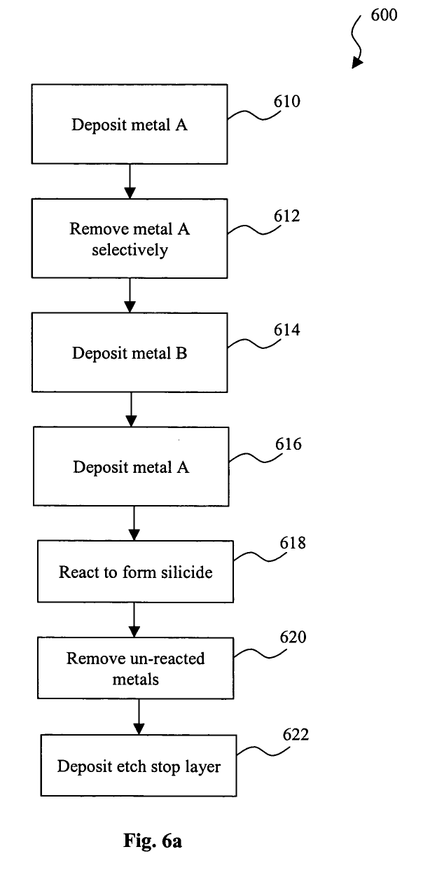

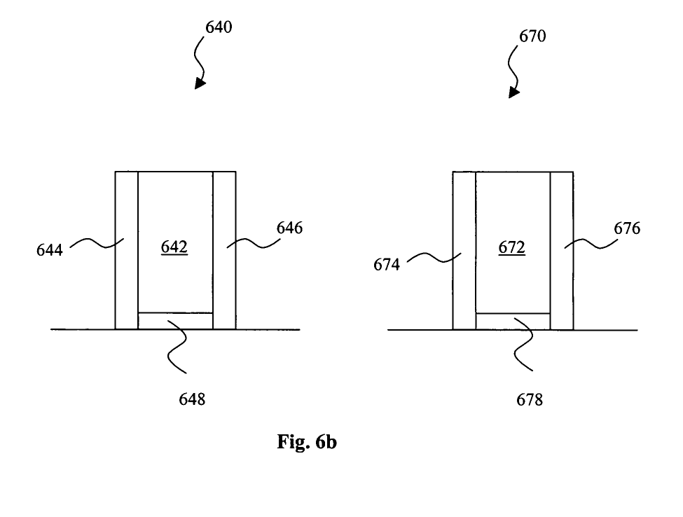

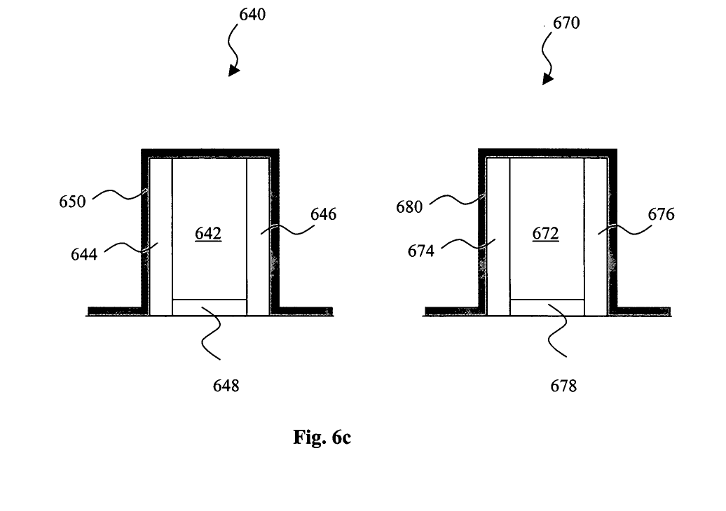

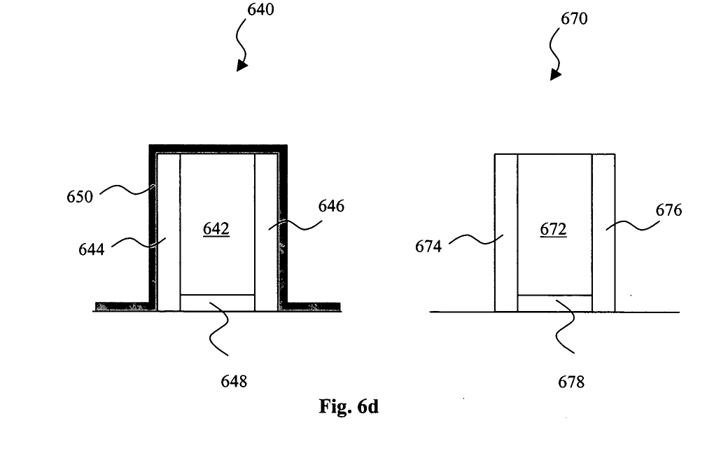

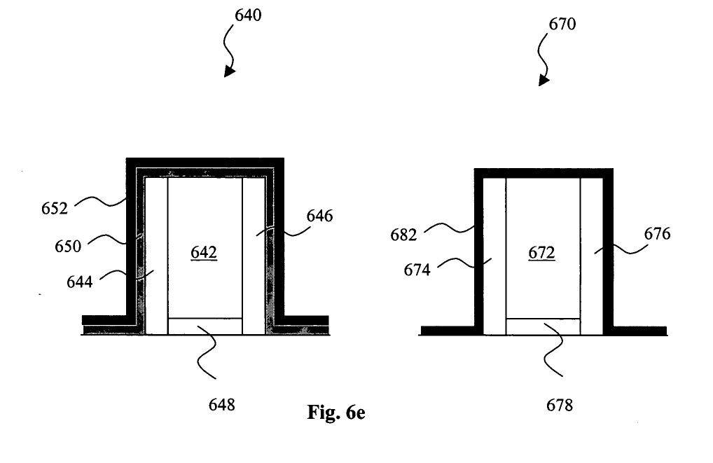

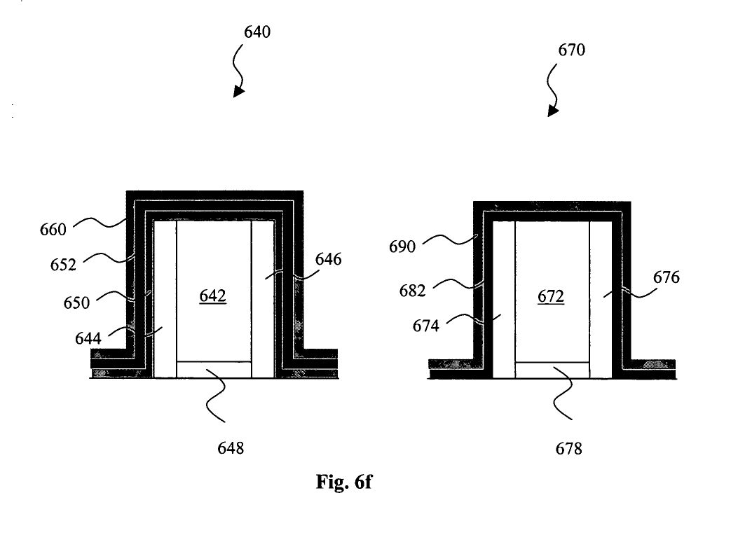

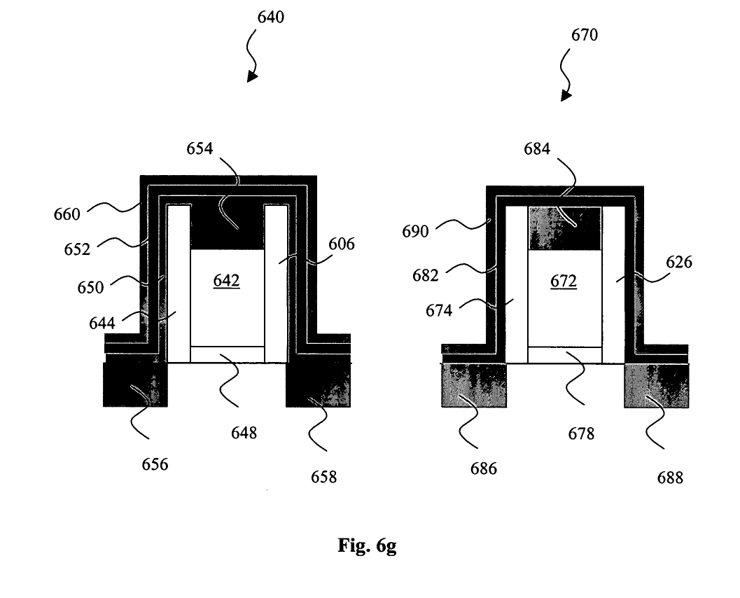

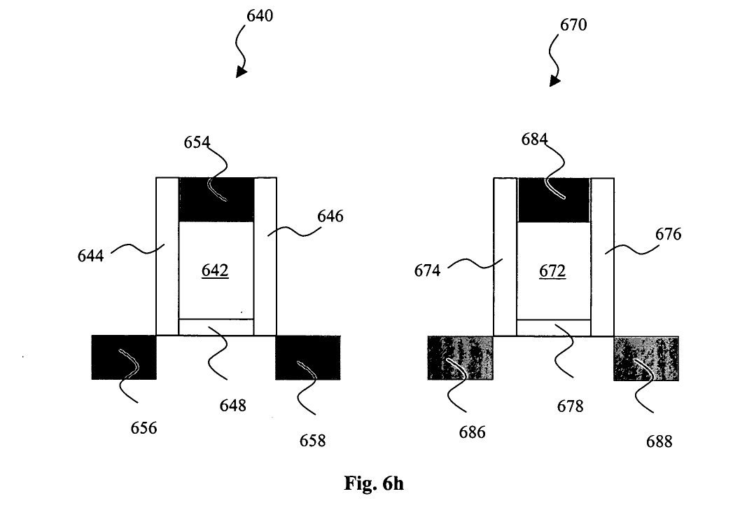

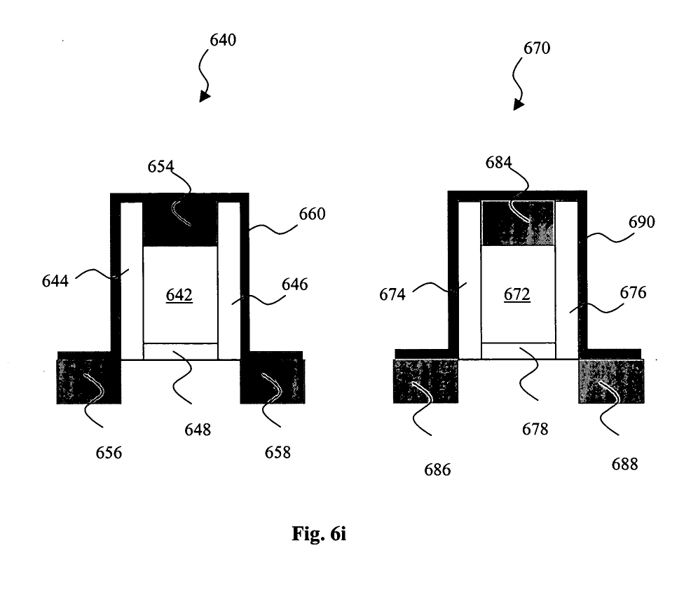

Referring now to FIG. 6a and with additional reference to FIGS. 6b-6i, in another embodiment, a method 600 may be used to form the complementary silicide structure of FIG. 1 with an NMOS and a PMOS. FIGS. 6b-6i illustrate cross-sectional views of an exemplary integrated circuit undergoing fabrication steps that correspond to steps of FIG. 6a. As the method 600 of FIG. 6a is described below in greater detail, the cross-sectional views in FIGS. 6b-6i may also be referred to for purposes of illustration. It is understood that the method 600 is not limited to the formation of a complementary silicide structure, but may be used to form any two regions during a semiconductor fabrication process where the first region has one composition or material ratio and the second region has a different composition or material ratio.

In the present example, the first region is an NMOS 640 and the second region is a PMOS 670, as illustrated in FIG. 6b. It is understood that portions of the NMOS 640 and PMOS 670 may be fabricated prior to the execution of the method 600. For example, the NMOS 640 includes a polycrystalline silicon gate 642, spacers 644 and 646, and a gate dielectric 648. The PMOS 670 includes a polycrystalline silicon gate 672, spacers 674 and 676, and a gate dielectric 678.

With specific reference now to FIGS. 6a and 6c, the method 600 begins in step 610 with the deposition of first metal portions 650, 680 (which are formed using the same metal ‘A’) over the NMOS 640 and PMOS 670, respectively. The first metal portions 650, 680 may be deposited using PVD or CVD process. The first metal portions 650, 680 may be nickel, cobalt, tungsten, tantalum, titanium, platinum, erbium, palladium, or any other metal able to interact with silicon at an elevated temperature to form silicide in a low resistance phase state. In the present example, the first metal portions 650, 680 comprise nickel, which may be deposited using a suitable process flow such as HF dipping, an argon pre-sputter etch to prepare the surface, and then nickel sputtering.

In step 612 and with additional reference to FIG. 6d, the first metal portion 680 may be removed selectively, leaving the first metal portion 650 intact. The first metal portion 680 may be selectively removed using such processes as photolithography and etching. Such processes may include forming photo-resist on both metal portions 650 and 680, transferring the etching pattern from a mask to the photo-resist, etching, and stripping. Alternatively, the etching may follow the stripping. It may be preferable to select the etching process based on the first metal portion 680.

In step 614 and with additional reference to FIG. 6e, second metal portions 652, 682 are deposited over the NMOS 640 and PMOS 670, respectively. The second metal portions 652, 682 are formed using the same metal (metal ‘B’), but it is a different metal or metal composition than that used to form the first metal portions 650, 680. The deposition process may use PVD or CVD. The second metal portions 652, 682 may comprise nickel, cobalt, tungsten, tantalum, titanium, platinum, erbium, palladium, or any other metal able to interact with silicon at an elevated temperature to form silicide in a low resistance phase state. In the present example, the second metal portions 652, 682 are cobalt.

In step 616 and with additional reference to FIG. 6f, third metal portions 660, 690 are deposited over the NMOS 640 and PMOS 670, respectively. The third metal portions 660, 690 are formed using the same metal (metal ‘A’) as the first metal portions 650, 680. This forms a “sandwich” structure on the NMOS 640 with a layer of metal B formed between two layers of metal A (e.g., nickel/cobalt/nickel). The deposition process may use PVD or CVD. The third metal portions 660, 690 may comprise nickel, cobalt, tungsten, tantalum, titanium, platinum, erbium, palladium, or any other metal able to interact with silicon at an elevated temperature to form silicide in a low resistance phase state. In the present example, the third metal portions 660, 690 are nickel. The nickel may be deposited by a process such as nickel sputtering, with a suitable process flow including HF dipping, an argon pre-sputter etch to prepare the surface, and then nickel sputtering.

In step 618 and with additional reference to FIG. 6g, a silicide is formed on both the NMOS 640 and the PMOS 670. However, the silicide formed on the NMOS 640 is different than the silicide formed the PMOS 670. This is because the silicide formed on the NMOS 640 is an alloy silicide that contains a relatively large amount of metal A (nickel), while silicide formed on the PMOS 670 contains a lesser amount of metal A. In other words, both are alloy silicides containing metals A and B (e.g., nickel and cobalt), but with different compositions.

As illustrated in FIG. 6g, silicide formed on the gate, source, drain of the NMOS 640 produces gate silicide 654, source silicide 656, and drain silicide 658. Silicide formed on the gate, source, and drain of the PMOS 670 produces gate silicide 684, source silicide 686, and drain silicide 688. The gate silicide 654, source silicide 656, and drain silicide 658 are alloy silicides with a relatively high level of metal A (nickel), while the gate silicide 684, source silicide 686, and drain silicide 688 are alloy silicides with a lower level of metal A. The A/B metal (e.g., nickel/cobalt) ratio in the alloy silicides may be adjusted to provide a desired work function by optimizing metal deposition processing and silicidation processing. Silicidation processing may be a reaction between the second metal (or first and second metals) and silicon (or poly-silicon) at an elevated temperature that is selected based on the specific metal or metals. Such reacted silicide may be in metastable phase and may need a second annealing step or RTA, thereby forming a stable silicide phase with reduced resistance. Such a second annealing step may also be implemented after the step 620 (described below) which removes un-reacted metal. It is understood that some silicides, such as nickel silicide, may be formed in a one step RTA at a lower temperature.

In step 620 and with additional reference to FIG. 6h, un-reacted metals may be removed from both the NMOS 640 and the PMOS 670, as well as other areas (not shown), such as an isolation structure. The metal that lies on isolation areas may not have reacted with an oxide or nitride layer, and may need to be selectively removed using a metal etching solution. This will leave intact the silicide on the polysilicon gate and source/drain contact areas.

In step 622 and with additional reference to FIG. 6i, contact etch stop layers 660 and 690 may be formed. As previously described, the contact etch stop layers 660 and 690 may have a relatively high resistance to contact etch processing and may be compatible with silicide. The material of the contact etch stop layers 660, 690 may be selected based on an insulator material (not shown) that is to be etched and an etchant that is to be used. For example, the contact etch stop layers 660, 690 may be formed using silicon nitride, silicon oxynitride, silicon carbide, or silicon oxide.

In the present example, the contact etch stop layers 660, 690 may be blanket deposited over all areas including the NMOS 640 and PMOS 670, although it is understood that a selective deposition process may be used. The selection of a particular deposition method may depend on the material used for the contact etch stop layers 660, 690, and may include PVD, CVD, or a thermal process, and may be completed in multiple steps. For example, a silicon nitride film may be selected for the contact etch stop layers 660, 690. The silicon nitride film may be formed by LPCVD, PECVD, or other known methods. For purposes of illustration, a PECVD process is used, which may provide low temperature processing that is compatible with the underlying structures. For PECVD, the deposition reaction may be silane and ammonia (or nitrogen) in a plasma. SiC may be formed by PECVD of trimethylsilane. The contact etch stop layers 660, 690 may be patterned using photolithography and etching, as is well known in the art.

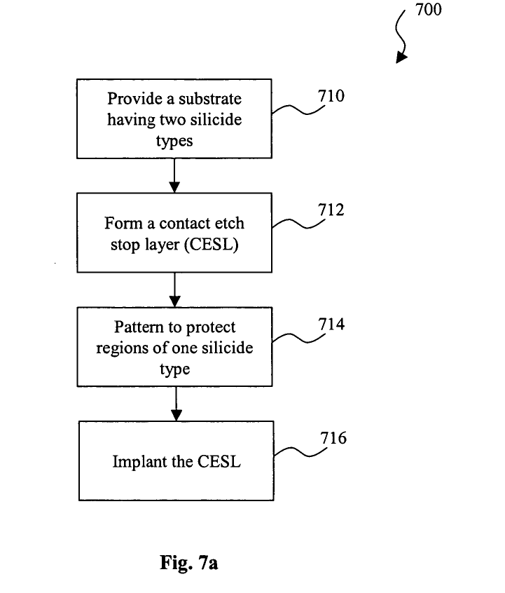

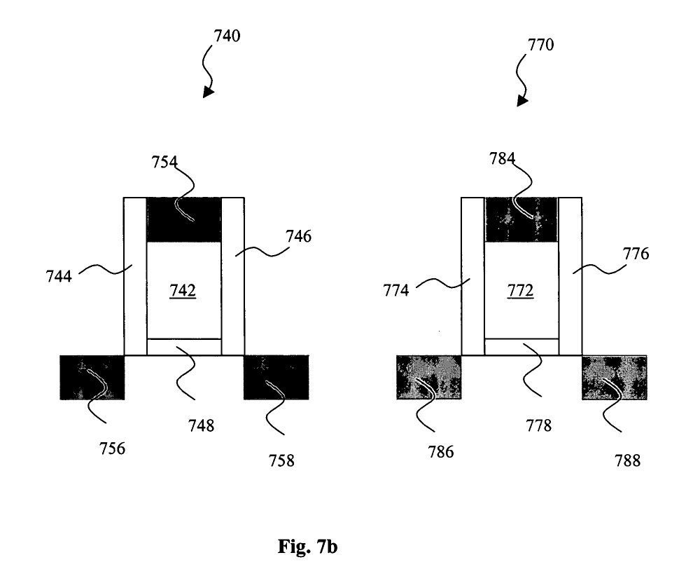

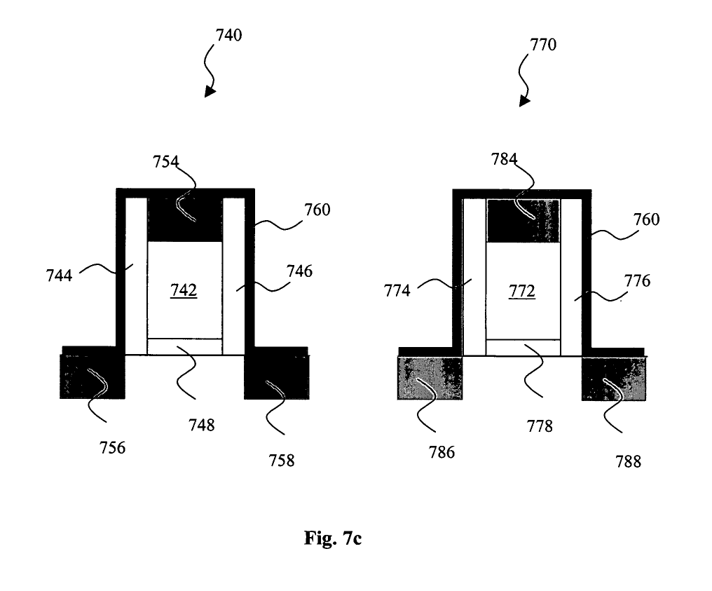

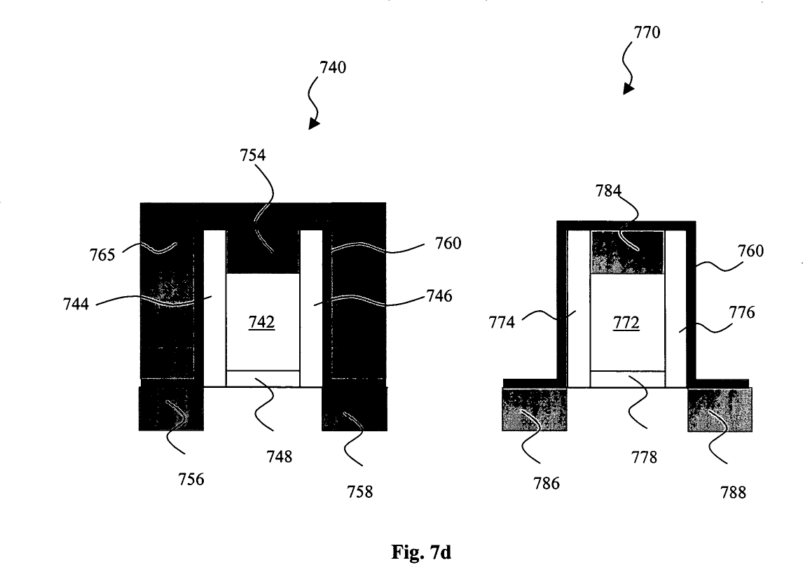

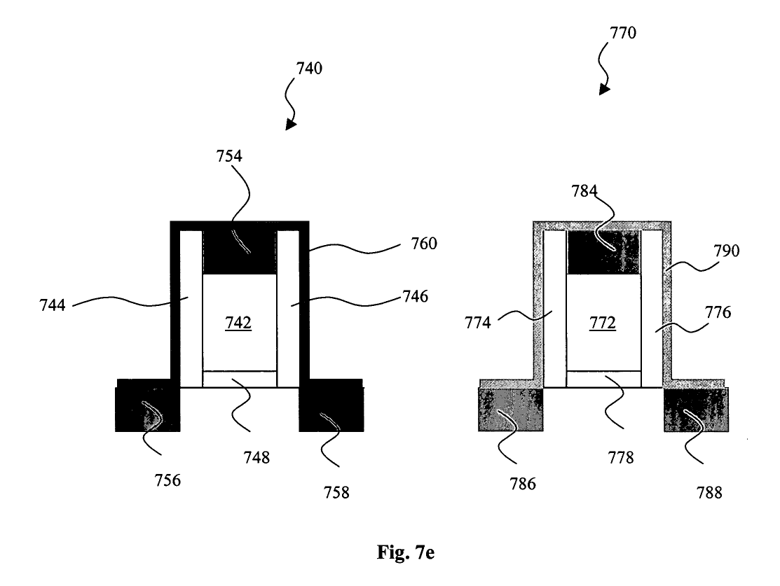

Referring now to FIG. 7a and with additional reference to FIGS. 7b-7e, in another embodiment, a method 700 may be used to form a dual CESL and a complementary silicide structure of FIG. 1 with an NMOS and a PMOS. FIGS. 7b-7e illustrate cross-sectional views of an exemplary integrated circuit undergoing fabrication steps that correspond to steps of FIG. 7a. As the method 700 of FIG. 7a is described below in greater detail, the cross-sectional views in FIGS. 7b-7e may also be referred to for purposes of illustration. It is understood that the method 700 is not limited to the formation of a complementary silicide and dual CESL structure.

In the present example, the method 700 begins at step 710 by providing a complementary silicide structure having a first region, such as an NMOS 740, and a second region, such as a PMOS 770, as illustrated in FIG. 7b. For example, the NMOS 740 includes a polycrystalline silicon (poly-Si) gate 742, spacers 744 and 746, a gate dielectric 748, and silicide features 754, 756, and 758 of a first silicide. The PMOS 770 includes a polycrystalline silicon gate 772, spacers 774 and 776, a gate dielectric 778, and silicide features 784, 786, and 788 of a second silicide. The complementary silicide structure of the NMOS 740 and PMOS 770 may be fabricated prior to the execution of the method 700. The complementary silicide structure of the NMOS 740 and PMOS 770 may be formed by a method substantially similar to one of the methods 200 to 600 prior to forming the CESL. For example, the complementary silicide structure of the NMOS 740 and PMOS 770 may be formed by a process including forming a first metal layer over the first region and the second region, selectively removing the first metal layer from the second region, forming a second metal layer over the first and second regions, forming silicide on the first and second regions, and removing un-reacted metals from the first and second regions.

With specific reference now to FIGS. 7a and 7c, the method 700 proceeds to step 712 to form a CESL 760 in both the NMOS 740 and the PMOS 770. The method to form the CESL 760 may be similar to methods described in methods 200 to 600.

In step 714 and with additional reference to FIG. 7d, an ion implantation mask 765 may be formed on the NMOS 740 by a patterning process such as a photolithography process. For example, a photoresist layer may be applied to the surface of the NMOS 740 and PMOS 770. The photoresist is then patterned using a photolithography process such that the photoresist layer over PMOS 770 is removed after development while the photoresist layer over NMOS 740 remains.

In step 716 and with additional reference to FIG. 7e, an ion implantation process is implemented while the NMOS 740 is protected by the ion implantation mask 765. The ion implantation process may partially release the stress of the CESL 760 in the PMOS region such that the CESL 760 in the PMOS region may be transformed into a CESL 790 having a different stress. The ions to be implanted may comprise germanium and/or other suitable ions. The implantation dose and energy may be tuned for desired stress.

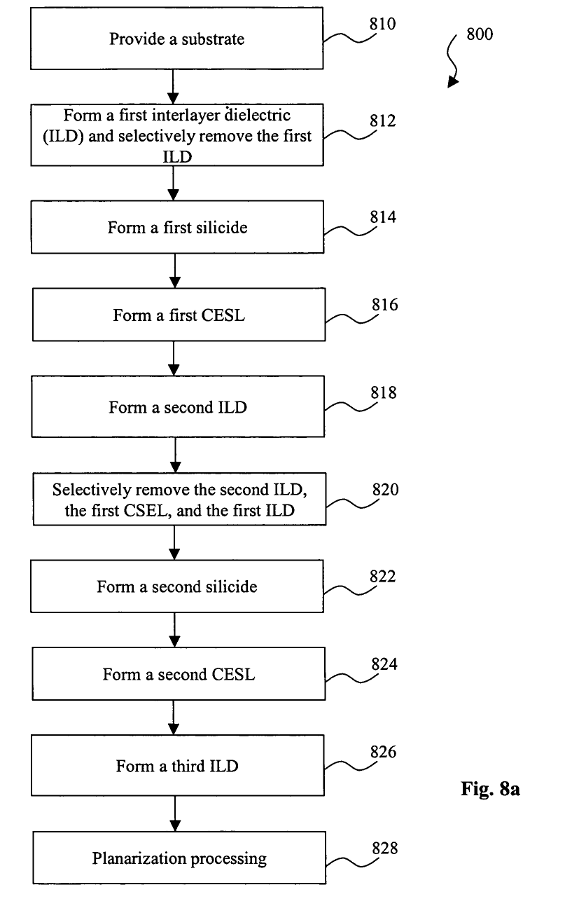

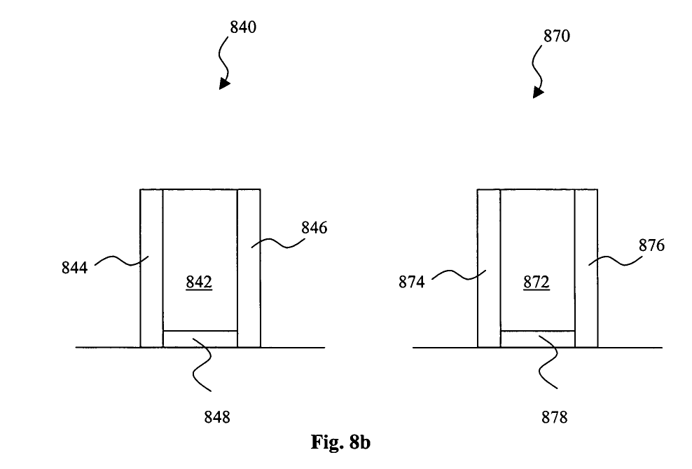

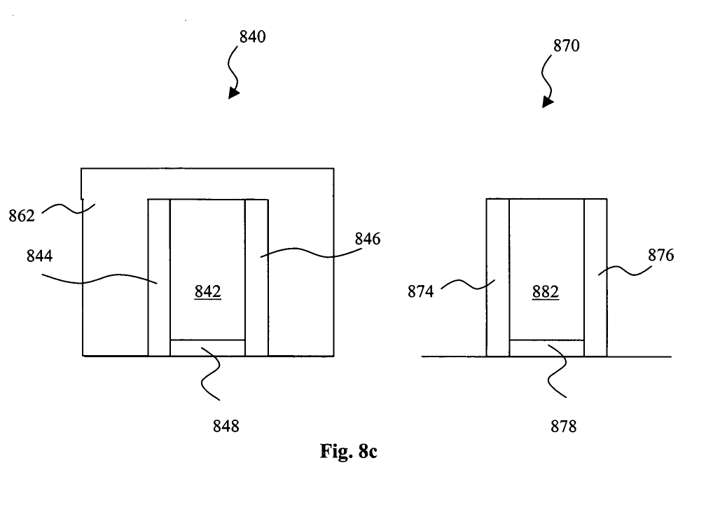

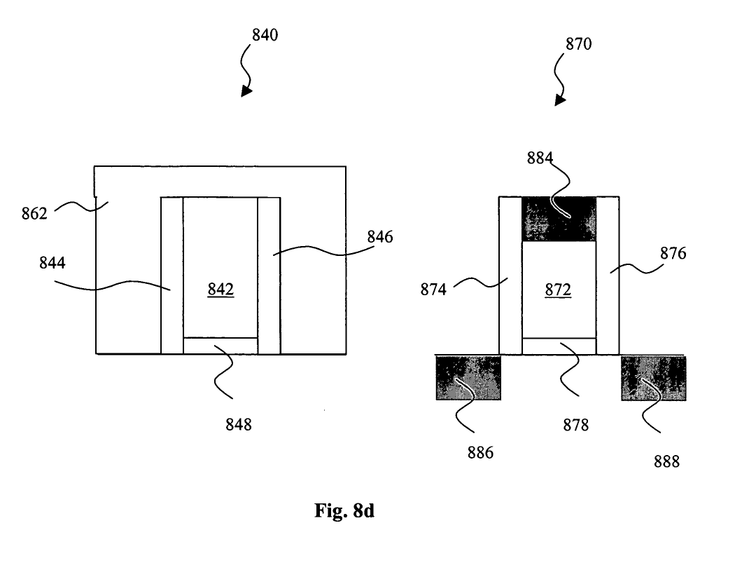

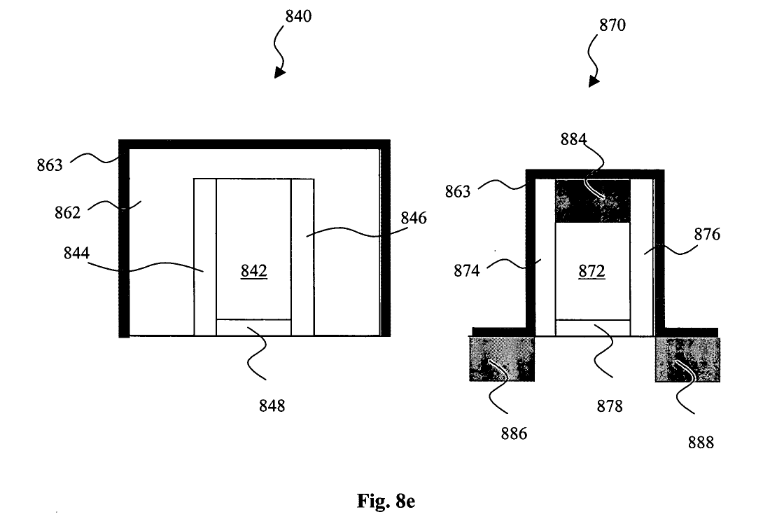

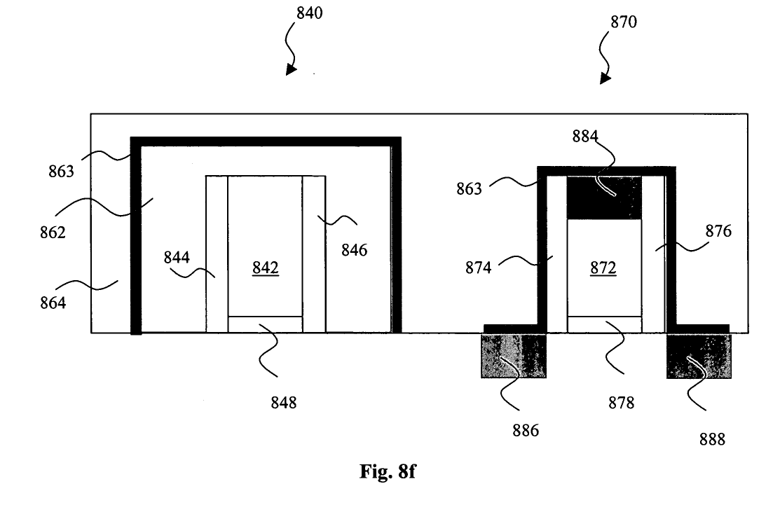

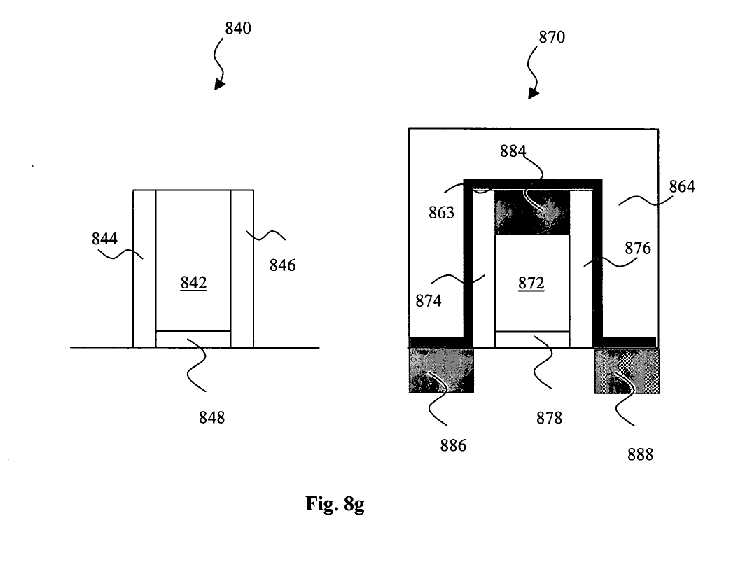

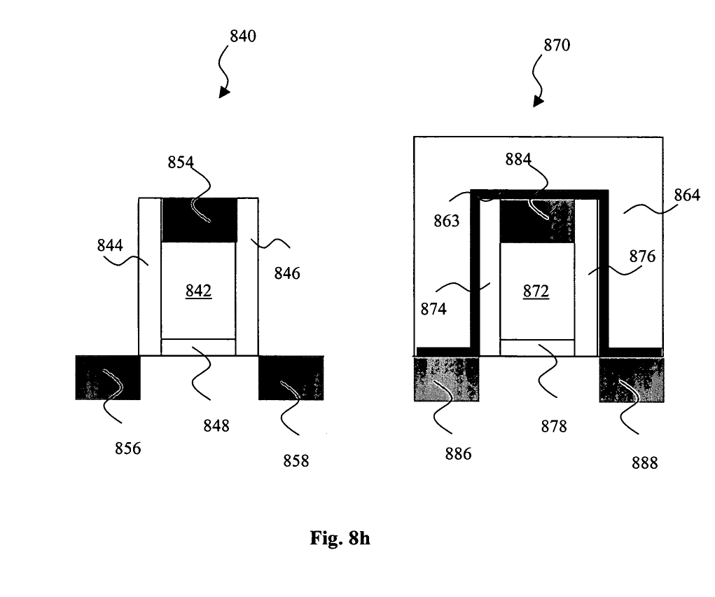

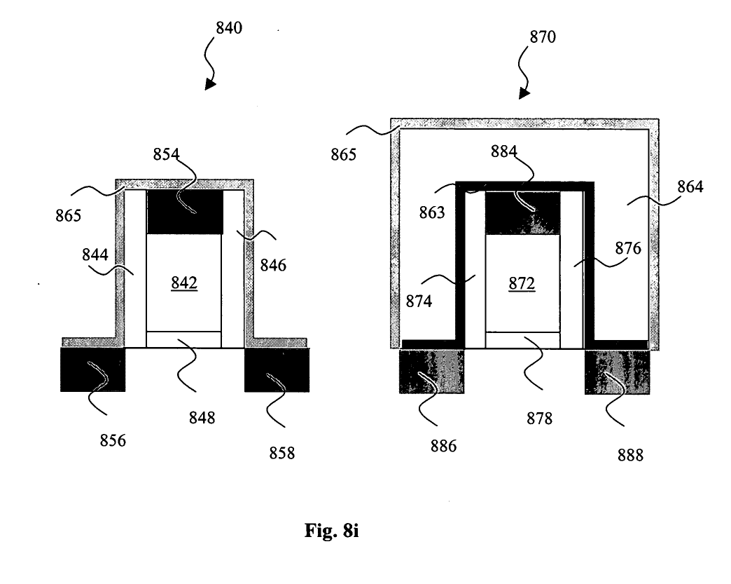

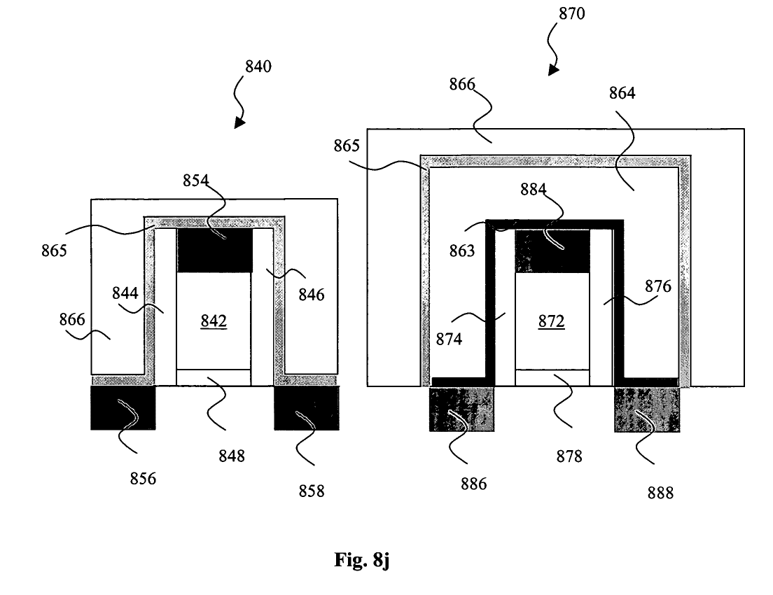

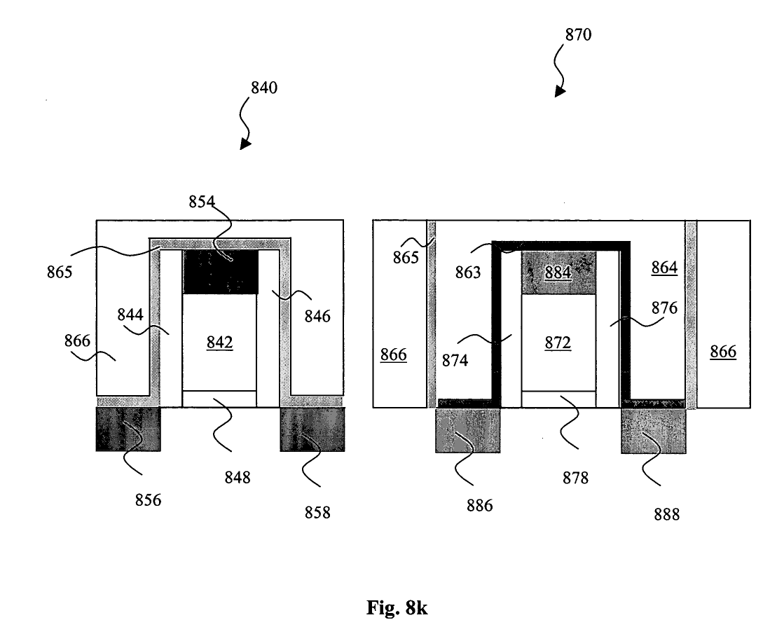

Referring now to FIG. 8a and with additional reference to FIGS. 8b-8k, in another embodiment, a method 800 may be used to form the structure of FIG. 1 having a complementary silicide and dual stress CESL structure. FIGS. 8b-8k illustrate cross-sectional views of an exemplary integrated circuit undergoing fabrication steps that correspond to steps of FIG. 8a. As the method 800 of FIG. 8a is described below in greater detail, the cross-sectional views in FIGS. 8b-8k may also be referred to for purposes of illustration. It is understood that the method 800 is not limited to the formation of a complementary silicide structure and a complementary CESL.

In the present example, the method 800 begins at step 810 by providing the first region, such as an NMOS 840, and the second region, such as a PMOS 870, as illustrated in FIG. 8b. It is understood that portions of the NMOS 840 and PMOS 870 may be fabricated prior to the execution of the method 800. For example, the NMOS 840 may include a polycrystalline silicon gate 842, spacers 844 and 846, and a gate dielectric 848. The PMOS 870 may include a polycrystalline silicon gate 872, spacers 874 and 876, and a gate dielectric 878.

With specific reference now to FIGS. 8a and 8c, the method 800 may proceed to step 812 to form a first interlayer dielectric (ILD) layer 862 and then selectively remove at least a portion thereof. The first ILD layer may be formed using a method known in the art and then selectively removed such that the NMOS 840 is underlying the first ILD 862 while the PMOS 870 is exposed.

In step 814 and with additional reference to FIG. 8d, silicide features 884, 886, and 888 of a first silicide are formed and disposed in the PMOS 870 by a suitable method using the first silicide material.

In step 816 and with additional reference to FIG. 8e, a first CESL 863 is formed over the NMOS 840 and the PMOS 870 by a method similar to methods described in the methods 200 to 700. The first CESL 863 may have a tensile stress. Composition and formation of the first CESL 863 may be similar to those of the CESL described in the methods 200 to 600. In one example, the first CESL 863 may comprise silicon nitride formed by a low pressure chemical vapor deposition (LPCVD). The stress of the first CESL 863 may be tuned by processing parameters including silicon/nitrogen ratio and deposition temperature. The stress may be further tuned by an ion implantation process such as germanium ion implantation.

In step 818 and with additional reference to FIG. 8f, a second ILD 864 may be formed over the first CESL 863 in the NMOS and PMOS regions.

In step 820, the second ILD 864, the first CESL 863, and the first ILD 862 are then selectively removed from the NMOS 840 region, as shown in FIG. 8g, by a method such as a photolithography and etching process.

In step 822, with reference to FIG. 8h, silicide features 854, 856, and 858 of a second silicide are formed in the NMOS 840 region by a method similar to the method of step 814, using a second silicide material.

In step 824, with reference to FIG. 8i, a second CESL 865 is formed over both the NMOS 840 and the PMOS 870 regions. The second CESL 865 may comprise a compressive stress. Composition and formation of the second CESL 865 may be similar to those described in the methods 200 to 600. In one example, the second CESL 865 may comprise silicon nitride formed by a plasma enhanced chemical vapor deposition (PECVD). The stress of the second CESL may be tuned by processing parameters such as silicon/nitrogen ratio and deposition temperature. The stress may be further tuned by an ion implantation process such as germanium ion implantation.

In step 826, referring to FIG. 8j, a third ILD layer 866 may be formed over the second CESL 865 of the NMOS 840 and the PMOS 870. In step 828, with reference to FIG. 8k, the NMOS 840 and the PMOS 870 may be planarized by a suitable process such as chemical mechanical planarization (CMP). The planarization process may remove the third ILD 866 and the second CESL 865 above the silicide feature 884 in the PMOS 870 and may partially remove the second ILD 864 in the same region such that the second ILD 864 in the PMOS 870 and the third ILD 866 in the NMOS 840 may be substantially coplanar.

The first, second, and third ILD layers 862, 864, and 866 may each comprise silicon dioxide, spin-on glass (SOG), fluoride-doped silicate glass (FSG), polyimide, carbon doped silicon oxide, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and/or other materials. The ILD layers may be formed by CVD, spin-on, PVD, atomic layer deposition (ALD), and/or other suitable processes.

The first and second CESLs 863 and 865 may each have a relatively high resistance to contact etch processing and may be compatible with the associated silicide. The composition and formation of the CESLs 863 and 865 may be chosen based on the second ILD 864 and the third ILD 866, respectively. For example, the contact etch stop layers 863 and 865 may each comprise silicon nitride, silicon oxynitride, silicon carbide, silicon oxide, and/or other suitable material.

Contacts for interconnects may be formed to both the NMOS and PMOS regions. For example, the second ILD 864 in the PMOS 870 and the third ILD 866 in the NMOS 840 may be patterned to form contact holes such that the contact holes extend to the silicide features 884, 886, and 888 in the PMOS 870 and the silicide features 854, 856, and 858 in the NMOS 840. For example, the ILD layers may be etched first and then the CESLs may be then etched in a sequential process. The patterning method may comprise photolithography and etching processes. The etching process may further comprise various steps to remove the ILD structure and the CESL such that the silicide features are exposed for connection. The contact hole may be filled with a conductive material substantially similar in composition to those of the gate electrodes 842 and 872. The filled conductive material may be planarized by a suitable process such as CMP to form contact features. Other interconnect features such as vias and metal lines may also be formed using suitable processes such as a dual damascene process.

The present disclosure provides an integrated circuit having a first active region and a second active region wherein the first active region may have an NMOS transistor with silicide features of a first type and a CESL structure of a tensile stress and the second active region may have a PMOS transistor with silicide features of a second type and a CESL structure of a compressive stress. The first and the second type of silicide features may provide reduced contact resistance with associated active regions. The CESL structures may help to optimize fabrication with reduced defects and easy control of the end point during contact hole formation. The first and second CESL structures may further enhance the performance of the integrated circuit by stress applied to the active regions. In one embodiment, the NMOS may have an enhanced carrier mobility by a tensile stress from the CESL and the PMOS may have an enhanced carrier mobility by a compressive stress from the CESL. In other embodiment, a CESL may only be formed and disposed on one of the first and second active regions.

In one embodiment, the present disclosure provides a semiconductor device having a first active region and a second active region formed in a substrate; a plurality of first silicide features having a first silicide formed in the first active region; a plurality of second silicide features having a second silicide formed in the second active region, wherein the second silicide differs from the first silicide and at least one of the first and second silicides is an alloy silicide; and an etch stop layer overlying at least one of the first and second active regions.

In the semiconductor device, at least one of the first and second active regions may comprise a raised source and drain, and/or a FinFET structure. The first active region may comprise an N-type metal oxide semiconductor (NMOS) transistor and the second active region may comprise a P-type metal oxide semiconductor (PMOS) transistor. The etch stop layer in the first and second active regions may have a first stress and second stress, respectively. In one example, the first stress is a tensile stress and the second stress is a compressive stress. In another example, the first stress has a tensile stress larger than 10⁹ pascal. The second stress has a compressive stress larger than 10⁹ pascal. The etch stop layer may comprise a material selected from the group consisting of a nitrogen-containing material, an oxygen-containing material, and combinations thereof. The etch stop layer may comprise a material selected from the group consisting of silicon nitride, silicon oxynitride, silicon oxide, a high dielectric-constant (K) material having a K value at least 10, and combinations thereof.

The semiconductor device of claim 1 may further comprise a contact structure formed in at least one opening wherein the at least one opening extends through the etch stop layer to at least one of the first and second silicide features.

In the semiconductor device, at least one of the first and second silicides may comprise a single metal silicide. The first and second silicide may each comprise a material selected from the group consisting of nickel silicide, cobalt silicide, tungsten silicide, tantalum silicide, platinum silicide, erbium silicide, palladium silicide, and combinations thereof.

In the semiconductor device, the first and second active regions may comprise gate dielectric features. The gate dielectric features may comprise a material selected from the group consisting of silicon oxide, silicon nitride, silicon oxynitride, a high dielectric constant (K) material, and combinations thereof. The high K material may have a dielectric constant at least 10. The high K material may comprise a material selected from the group consisting of metal oxides, metal nitrides, metal silicates, transition metal-oxides, transition metal-nitrides, transition metal-silicates, oxynitrides of metals, metal aluminates, zirconium silicate, zirconium aluminate, HfO₂, ZrO₂, ZrOₓN_{y}, HfOₓN_{y}, HfSiₓO_{y}, ZrSiₓO_{y}, HfSiₓO_{y}N_{z}, ZrSiₓO_{y}N_{z}, Al₂O₃, TiO₂, Ta₂O₅, La₂O₃, CeO₂, Bi₄Si₂O₁₂, WO₃, Y₂O₃, LaAlO₃, Ba₁₋ₓSrₓTiO₃, PbTiO₃, PST, PZN, PZT, PMN, and combinations thereof.

In the semiconductor device, the first and second active regions may comprise gate electrodes. The gate electrodes may comprise a material selected from the group consisting of silicon-containing material, germanium-containing material, metal-containing material, and combinations thereof. The gate electrodes may comprise a material selected from the group consisting of poly-Si, poly-SiGe, metal, metal silicide, metal nitride, metal oxide, and combinations thereof.

In the semiconductor device, the substrate may comprise an elementary semiconductor such as silicon and germanium. The substrate may comprise a compound semiconductor. The substrate may comprise an alloy semiconductor, including a material selected from the group consisting of a silicon-containing material, a germanium-containing material, and a carbon-containing material. The alloy semiconductor may comprise silicon germanium. The substrate may comprise a gradient silicon germanium structure. The substrate may comprise a semiconductor on insulator (SOI) structure such as a silicon on insulator feature.

The present disclosure has been described relative to a preferred embodiment. Improvements or modifications that become apparent to persons of ordinary skill in the art only after reading this disclosure are deemed within the spirit and scope of the application. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

1. A semiconductor device comprising:
a substrate have a first active region and a second active region;
a plurality of first silicide features formed of a first silicide in the first active region;
a plurality of second silicide features formed of a second silicide in the second active region, wherein the second silicide differs from the first silicide and at least one of the first and second silicides is an alloy silicide; and
an etch stop layer overlying at least one of the first and second active regions.

2. The semiconductor device of claim 1 wherein the first active region comprises an N-type metal oxide semiconductor (NMOS) transistor and the second active region comprises a P-type metal oxide semiconductor (PMOS) transistor.

3. The semiconductor device of claim 1 wherein the etch stop layer has a first stress and second stress in the first and second active regions, respectively.

4. The semiconductor device of claim 3 wherein the first stress is a tensile stress and the second stress is a compressive stress.

5. The semiconductor device of claim 4 wherein the tensile stress is larger than 10⁹ pascal.

6. The semiconductor device of claim 4 wherein the compressive stress is larger than 10⁹ pascal.

7. The semiconductor device of claim 1 wherein the etch stop layer comprises a material selected from the group consisting of a nitrogen-containing material, an oxygen-containing material, and combinations thereof.

8. The semiconductor device of claim 1 wherein the etch stop layer comprises a material selected from the group consisting of silicon nitride, silicon oxynitride, silicon oxide, a high dielectric-constant (K) material having a K value at least 10, and combinations thereof.

9. The semiconductor device of claim 1 further comprising a contact feature formed in at least one opening wherein the at least one opening extends through the etch stop layer to at least one of the first silicide features and the second silicide features.

10. The semiconductor device of claim 1 wherein at least one of the first and second silicides comprises a single metal silicide.

11. The semiconductor device of claim 1 wherein the first and second silicide each comprises a material selected from the group consisting of nickel silicide, cobalt silicide, tungsten silicide, tantalum silicide, platinum silicide, erbium silicide, palladium silicide, and combinations thereof.

12. The semiconductor device of claim 1 wherein the first and second active regions comprise gate dielectric features.

13. The semiconductor device of claim 12 wherein the gate dielectric features comprise a material selected from the group consisting of silicon oxide, silicon nitride, silicon oxynitride, a high dielectric constant (K) material, and combinations thereof.

14. The semiconductor device of claim 13 wherein the high K material has a dielectric constant at least 10.

15. The semiconductor device of claim 13 wherein the high K material comprises a material selected from the group consisting of metal oxides, metal nitrides, metal silicates, transition metal-oxides, transition metal-nitrides, transition metal-silicates, oxynitrides of metals, metal aluminates, zirconium silicate, zirconium aluminate, HfO₂, ZrO₂, ZrOₓN_{y}, HfOₓN_{y}, HfSiₓO_{y}, ZrSiₓO_{y}, HfSiₓO_{y}N_{z}, ZrSiₓO_{y}N_{z}, Al₂O₃, TiO₂, Ta₂O₅, La₂O₃, CeO₂, Bi₄Si₂O₁₂, WO₃, Y₂O₃, LaAlO₃, Ba₁₋ₓSrₓTiO₃, PbTiO₃, BaTiO₃, SrTiO₃, PbZrO₃, PST, PZN, PZT, PMN, and combinations thereof.

16. The semiconductor device of claim 1 wherein the first and second active regions comprise gate electrodes.

17. The semiconductor device of claim 16 wherein the gate electrodes comprise a material selected from the group consisting of silicon-containing material, germanium-containing material, metal-containing material, and combinations thereof.

18. The semiconductor device of claim 17 wherein the gate electrodes comprise a material selected from the group consisting of poly-Si, poly-SiGe, metal, metal silicide, metal nitride, metal oxide, and combinations thereof.

19. The semiconductor device of claim 1 wherein at least one of the first and second active regions comprises a raised source and drain.

20. The semiconductor device of claim 1 wherein at least one of the first and second active regions comprises a FinFET structure.

21. The semiconductor device of claim 1 wherein the substrate comprises an elementary semiconductor.

22. The semiconductor device of claim 21 wherein the elementary semiconductor comprises a material selected from the group consisting of silicon and germanium.

23. The semiconductor device of claim 1 wherein the substrate comprises a compound semiconductor.

24. The semiconductor device of claim 1 wherein the substrate comprises an alloy semiconductor.

25. The semiconductor device of claim 24 wherein the alloy semiconductor comprises a material selected from the group consisting of a silicon-containing material, a germanium-containing material, and a carbon-containing material.

26. The semiconductor device of claim 25 wherein the alloy semiconductor comprises silicon germanium.

27. The semiconductor device of claim 1 wherein the substrate comprises a gradient silicon germanium structure.

28. The semiconductor device of claim 1 wherein the substrate comprises a semiconductor on insulator (SOI) structure.

29. The semiconductor device of claim 28 wherein the SOI structure comprises a silicon on insulator feature.

30. A method of fabricating a semiconductor device, comprising:
providing a substrate having first and second regions, wherein the first and second regions comprise a first silicide and a second silicide, respectively;
forming an etch stop layer having a first stress over the first and second regions;
forming a mask layer on the first region;
ion implanting the etch stop layer after forming the mask layer on the first region; and
removing the mask layer after ion implanting the etch stop layer.

31. The method of claim 30 wherein forming the etch stop layer comprises a process selected from the group consisting of chemical vapor deposition (CVD) and physical vapor deposition (PVD).

32. The method of claim 30 wherein forming the mask layer on the first region comprises forming a photoresist layer on the first region using a photolithography process.

33. A method of fabricating a semiconductor device, comprising:
providing a substrate having first and second regions;
forming a first metal layer on the first and second regions;
selectively removing the first metal layer from the second region;
forming a second metal layer on the first and second regions;
forming silicide on the first and second regions; and
forming an etch stop layer on the first and second regions after forming the silicide.

34. The method of claim 33 wherein forming the first metal layer, the second metal layer, and the etch stop layer each comprises using a process selected from the group consisting of chemical vapor deposition (CVD) and physical vapor deposition (PVD).

35. The method of claim 33 further comprising ion implanting the etch stop layer in the second region after forming a mask layer on the first region.

36. A method of fabricating a semiconductor device, comprising:
providing a substrate having first and second regions;
forming an N-type metal oxide semiconductor (NMOS) transistor in the first region and forming a P-type metal oxide semiconductor (PMOS) transistor in the second region;
forming a first dielectric layer on the first and second regions;
removing the first dielectric layer from the first region;
forming a first metal layer on the first and second regions;
forming first silicide features in the first region;
forming a tensile etch stop layer on the first and second regions;
forming a second dielectric layer on the first and second regions;
removing the second dielectric layer, the tensile etch stop layer, and the first dielectric layer from the second region;
forming a second metal layer on the first and second regions;
forming second silicide features in the second region;
forming a compressive etch stop layer on the first and second regions;
forming a third dielectric layer on the first and second regions; and
planarizing the first and second regions.

37. The method of claim 36 planarizing the first and second region comprises a chemical mechanical planarization (CMP) process.

38. The method of claim 36 wherein planarizing the first and second region comprises removing the third dielectric layer and second etch stop layer from the second region.

39. The method of claim 38 wherein planarizing the first and second region comprises partially removing the second dielectric layer from the second region.

40. The method of claim 36 wherein forming the first metal layer, the second metal layer, the first etch stop layer, the second etch stop layer, the first dielectric layer, the second dielectric layer, and the third dielectric layer each comprises using a process selected from the group consisting of chemical vapor deposition (CVD) and physical vapor deposition (PVD).

41. A method of fabricating a semiconductor device, comprising:
providing a substrate having first and second regions, wherein the first and second regions comprise a first silicide and a second silicide, respectively;
forming a first etch stop layer having a first stress in the first region;
forming a second etch stop layer having a second stress in the second region;
forming a dielectric layer over the first and second etch stop layers on the first and second regions; and
forming a plurality of contact holes to the substrate through the dielectric layer and through one of the first and second etch stop layers.

42. The method of claim 41 wherein forming a plurality of contact holes comprises etching the dielectric layer.

43. The method of claim 41 wherein forming a plurality of contact holes comprises etching at least one of the first and second etch stop layers.
